(19) United States
(12) Patent Application Publication
(10) Pub. No.: US 2026/0107590 A1
(43) Pub. Date: Apr. 16, 2026

(54) PIXEL AND IMAGE SENSOR INCLUDING THE SAME

(71) Applicant: Samsung Electronics Co., Ltd., Suwon-si (KR)

(72) Inventors: Masato FUJITA, Suwon-si (KR); Yunhyeok KIM, Suwon-si (KR)

(73) Assignee: Samsung Electronics Co., Ltd., Suwon-si (KR)

(21) Appl. No.: 19/220,995

(22) Filed: May 28, 2025

(30) Foreign Application Priority Data
Oct. 14, 2024 (KR) 10-2024-0139123

(51) Int. Cl. H10F 39/00; H10F 39/18

(52) U.S. Cl. CPC H10F 39/80373; H10F 39/1865; H10F 39/807

(57) ABSTRACT

A pixel of an image sensor includes a first photoelectric conversion region, a second photoelectric conversion region, a first floating diffusion region, a second floating diffusion region, a first transfer gate, a second transfer gate disposed, a first pixel transistor and a bridge region. The first pixel transistor includes a first source-drain region, a second source-drain region and a first pixel gate. The first pixel gate is disposed above the semiconductor substrate between the first source-drain region and the second source-drain region, and a pixel power voltage is applied to the second source-drain region. The bridge region is disposed below the second source-drain region to which the pixel power voltage is applied and forming an overflow barrier potential to discharge redundant photo-charges from the first photoelectric conversion region and the second photoelectric conversion region to the second source-drain region.

### CROSS-REFERENCE TO RELATED APPLICATION

This U.S. non-provisional application claims priority under 35 USC § 119 to Korean Patent Application No. 10-2024-0139123, filed on Oct. 14, 2024, in the Korean Intellectual Property Office (KIPO), the disclosure of which is incorporated by reference herein in its entirety.

### BACKGROUND

### 1. Technical Field

Example embodiments relate generally to semiconductor integrated circuits, and more particularly to a pixel and an image sensor including the pixel.

### 2. Discussion of the Related Art

Complementary metal oxide semiconductor (CMOS) image sensors are solid-state sensing devices that use complementary metal oxide semiconductors. CMOS image sensors have lower manufacturing costs and/or lower power consumption compared with charge-coupled device (CCD) image sensors. Thus, CMOS image sensors are used for various electronic appliances including portable devices such as, for example, smartphones and digital cameras.

A pixel array included in a CMOS image sensor may include a photoelectric conversion element such as a photodiode in each pixel. The photoelectric conversion element generates an electrical signal that varies based on the quantity of incident light. The CMOS image sensor processes electrical signals to synthesize an image. With the recent proliferation of higher-resolution images, pixels included in the CMOS image sensor are becoming much smaller. When the pixels get smaller, incident light may not be properly sensed and/or noise may occur due to interference between more highly integrated elements. Also, the CMOS image sensor may be required to have enhanced image quality and/or to perform additional functions, such as auto focusing.

### SUMMARY

Some example embodiments may provide a pixel having enhanced electrical characteristics, and an image sensor including the pixel.

According to example embodiments, a pixel of an image sensor includes a first photoelectric conversion region and a second photoelectric conversion region in a lower portion of a semiconductor substrate, the first photoelectric conversion region and the second photoelectric conversion region spaced apart from each other in a first horizontal direction; a first floating diffusion region and a second floating diffusion region in an upper portion of the semiconductor substrate, a first transfer gate and a second transfer gate above the semiconductor substrate, a first pixel transistor of the first transfer gate in a second horizontal direction perpendicular to the first horizontal direction; and a bridge region. The first pixel transistor includes a first source-drain region in the upper portion of the semiconductor substrate, a second source-drain region in the upper portion of the semiconductor substrate, and a first pixel gate above the semiconductor substrate and between the first source-drain region and the second source-drain region, and the second source-drain region configured to receive a pixel power voltage. The bridge region is below the second source-drain region is configured to form an overflow barrier potential such that redundant photo-charges from the first photoelectric conversion region and the second photoelectric conversion region are discharged to the second source-drain region.

According to example embodiments, an image sensor includes a pixel array including a plurality of pixels configured to perform a sensing operation by collecting photo-charges generated by incident light, a row driver portion to drive the pixel array in units of rows, and a controller configured to control the pixel array and the row driver. A pixel of the plurality of pixels includes a first photoelectric conversion region and a second photoelectric conversion region in a lower portion of a semiconductor substrate, the first photoelectric conversion region and the second photoelectric conversion region spaced apart from each other in a first horizontal direction, a first floating diffusion region and a second floating diffusion region in an upper portion of the semiconductor substrate, a first transfer gate and a second transfer gate above the semiconductor substrate, a first pixel transistor on a side of the first transfer gate in a second horizontal direction perpendicular to the first horizontal direction, and a bridge region. The first pixel transistor includes a first source-drain region in the upper portion of the semiconductor substrate, a second source-drain region in the upper portion of the semiconductor substrate, and a first pixel gate above the semiconductor substrate and between the first source-drain region and the second source-drain region, and the second source-drain region is configured to receive a pixel power voltage. The bridge region is below the second source-drain region and is configured to form an overflow barrier potential such that redundant photo-charges from the first photoelectric conversion region and the second photoelectric conversion region are discharged to the second source-drain region.

According to example embodiments, a pixel of an image sensor, includes, a first photoelectric conversion region in a lower portion of a semiconductor substrate, a first floating diffusion region in an upper portion of the semiconductor substrate, a first transfer gate above the semiconductor substrate, a second photoelectric conversion region in the lower portion of the semiconductor substrate and spaced apart from the first photoelectric conversion region in a first horizontal direction, a second floating diffusion region in the upper portion of the semiconductor substrate and spaced apart from the first floating diffusion region in the first horizontal direction, a second transfer gate above the semiconductor substrate and spaced apart from the first transfer gate in the first horizontal direction, a first source-drain region and a second source-drain region in the upper portion of the semiconductor substrate, the second source-drain region configured to receive a pixel power voltage, a first pixel gate above the semiconductor substrate between the first source-drain region and the second source-drain region, a third source-drain region and a fourth source-drain region in the upper portion of the semiconductor substrate, the fourth source-drain region configured to receive a pixel power voltage, a second pixel gate above the semiconductor substrate between the third source-drain region and the fourth source-drain region, and at least one bridge region below at least one of the second source-drain region and the fourth source-drain region, the at least one bridge region configured to form an overflow barrier potential such that redundant photo-charges from the first photoelectric conversion region and the second photoelectric conversion region are discharged to the at least one of the second source-drain region or the fourth source-drain region.

The pixel and the image sensor according to example embodiments may more efficiently improve the electrical characteristics of the pixel and the image sensor by adding only the bridge region of the simple structure to provide the overflow path.

### BRIEF DESCRIPTION OF THE DRAWINGS

Example embodiments of the present disclosure will be more clearly understood from the following detailed description taken in conjunction with the accompanying drawings.

FIG. 1 is a plan view illustrating a layout of a pixel included in an image sensor according to some example embodiments.

FIGS. 2 through 5 are cross-sectional diagrams illustrating examples of a vertical structure of a pixel according to some example embodiments.

FIGS. 6 and 7 are diagrams illustrating an example of manufacturing a pixel according to some example embodiments.

FIG. 8 is a cross-sectional diagram illustrating a pixel according to some example embodiments.

FIG. 9 is a diagram illustrating an example of manufacturing the pixel of FIG. 8 according to some example embodiments.

FIGS. 10 through 13 are diagrams illustrating a pixel according to some example embodiments.

FIG. 14 is a block diagram illustrating an image sensor according to some example embodiments.

FIG. 15 is a circuit diagram illustrating an example of a unit circuit included in an image sensor according to some example embodiments.

FIG. 16 is a timing diagram illustrating an example operation of an image sensor according to some example embodiments.

FIG. 17 is a circuit diagram illustrating a configuration of pixels and a readout circuit included in an image sensor according to some example embodiments.

FIGS. 18 and 19 are plan views illustrating example embodiments of a layout of an image sensor corresponding to the configuration of FIG. 17.

FIG. 20 is a circuit diagram illustrating a configuration of pixels and a readout circuit included in an image sensor according to some example embodiments.

FIG. 21 is a plan view illustrating an example of a layout of an image sensor corresponding to the configuration of FIG. 20 according to some example embodiments.

FIG. 22 is a circuit diagram illustrating a configuration of a readout circuit included in an image sensor according to some example embodiments.

FIGS. 23 and 24 are plan views illustrating examples of a layout of an image sensor corresponding to the configuration of FIG. 22 according to some example embodiments.

FIG. 25 is a circuit diagram illustrating a configuration of a readout circuit included in an image sensor according to some example embodiments.

FIGS. 26 and 27 are plan views illustrating examples of a layout of an image sensor corresponding to the configuration of FIG. 25 according to some example embodiments.

FIG. 28 is a diagram illustrating overflow of a pixel according to some example embodiments.

FIG. 29 is a diagram illustrating a layout of a pixel array included in an image sensor according to some example embodiments.

FIGS. 30 through 33 are plan views illustrating examples of an arrangement pattern of a pixel array included in an image sensor according to some example embodiments.

FIG. 34 is a block diagram illustrating an electronic device according to some example embodiments.

FIG. 35 is a block diagram illustrating a camera module included in the electronic device of FIG. 34.

### DETAILED DESCRIPTION OF THE EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

Spatially relative terms, such as “lower,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, “included in” the range of “X” to “Y” includes all values between X and Y, including X and Y.

Although the numerical indicators such as “first,” “second,” “third,” etc., may be used herein to describe various elements, components, regions, layers, and/or sections, these indicators are only used to distinguish one element, component, region, layer, or section, from another region, layer, or section. These elements, components, regions, layers, and/or sections, should not be otherwise limited by these terms, and, for example, a first element, component, region, layer, or section, discussed below may be alternatively termed a second element, component, region, layer, or section, without departing from the scope of this disclosure.

Additionally, units or modules that process at least one function or operation may be realized by and/or include processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may, for example, include electrical components such as at least one of transistors, resistors, capacitors, etc., and/or electronic circuits including said components.

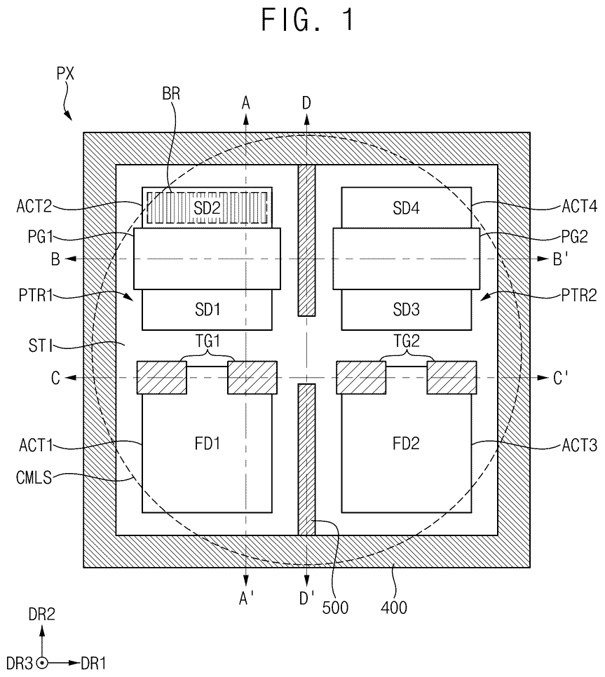

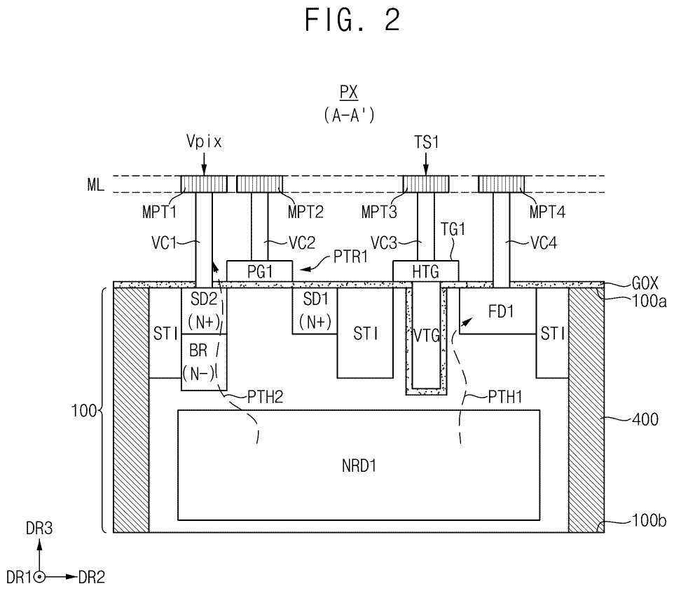

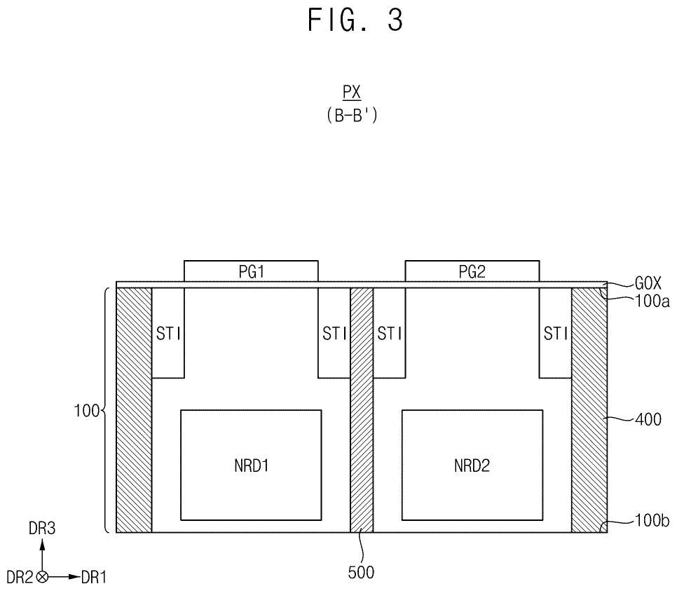

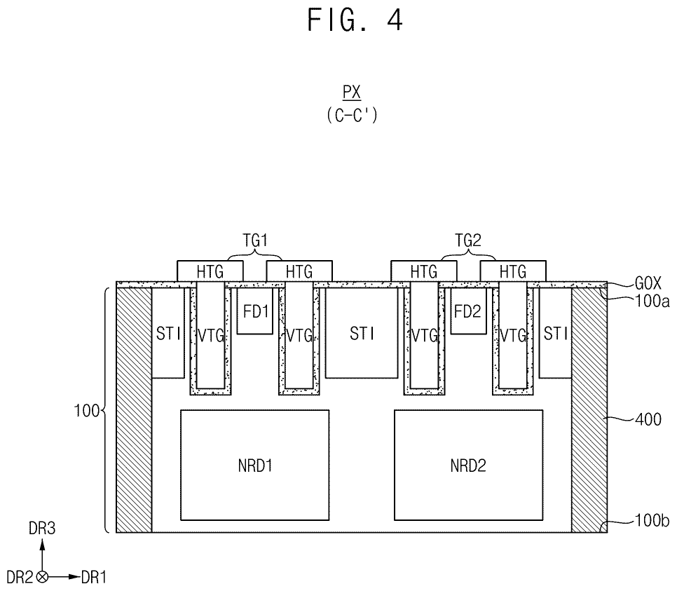

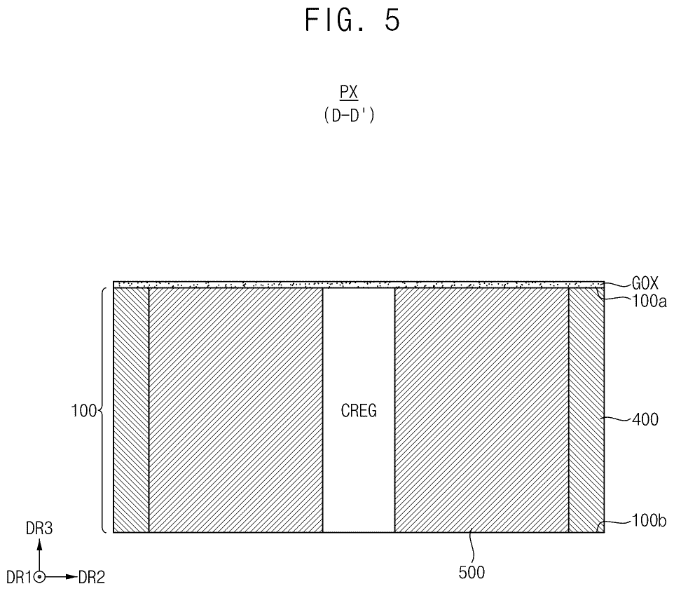

FIG. 1 is a plan view illustrating a layout of a pixel included in an image sensor according to some example embodiments, and FIGS. 2 through 5 are cross-sectional diagrams illustrating examples of a vertical structure of a pixel according to some example embodiments. FIG. 2 is a cross-sectional view cut along an A-A′ line of FIG. 1, FIG. 3 is a cross-sectional view cut along a B-B′ line of FIG. 1, FIG. 4 is a cross-sectional view cut along a C-C′ line of FIG. 1, and FIG. 5 is a cross-sectional view cut along a D-D′ line of FIG. 1.

Herein, two directions parallel to and intersecting a first surface 100a (front or top surface) and/or a second surface 100b (back or bottom surface) of the semiconductor substrate 100 are a first horizontal direction DR1 and a second horizontal direction DR2, and a direction substantially perpendicular to the first and/or second surfaces 100a and 100b of the semiconductor substrate 100 is a vertical direction DR3. The first horizontal direction DR1 and the second horizontal direction DR2 may be orthogonal to each other. The first horizontal direction DR1 may correspond to a row direction and the second horizontal direction DR2 may correspond to a column direction.

Referring to FIGS. 1 through 5, a pixel PX may include a first sub-pixel, a second sub-pixel, a first pixel transistor PTR1, a second pixel transistor PTR2, and a bridge region BR.

The first sub-pixel may include a first photoelectric conversion region NRD1, a first floating diffusion region FD1, and a first transfer gate TG1. The second sub-pixel may include a second photoelectric conversion region NRD2, a second floating diffusion region FD2, and a second transfer gate TG2. FIGS. 1 and 4 illustrate example embodiments in which each transfer gate is implemented as a pair of two opposing gates, but the example embodiments are not limited thereto.

The first photoelectric conversion region NRD11 and the second photoelectric conversion region NRD12 may be spaced apart from each other in a horizontal direction (e.g., the first horizontal direction DR1) and disposed in a lower portion of the semiconductor substrate 100. The first floating diffusion region FD1 and the second floating diffusion region FD2 may be spaced apart from each other in the first horizontal direction DR1 and disposed in an upper portion of the semiconductor substrate 100. The first transfer gate TG1 and the second transfer gate TG2 may be disposed above the semiconductor substrate 100 spaced apart from each other in the first horizontal direction DR1.

The first pixel transistor PTR1 may include a first source-drain region SD1, a second source-drain region SD2, and a first pixel gate PG1. The second pixel transistor PTR2 may include a third source-drain region SD3, a fourth source-drain region SD4, and a second pixel gate PG2.

The first pixel transistor PTR1 may be disposed on a side of the first transfer gate TG1 in a horizontal direction (e.g., the second horizontal direction DR2). The second pixel transistor PTR2 may be disposed on the side of the second transfer gate TG2 in the second horizontal direction DR2.

The first source-drain region SD1 and the second source-drain region SD2 may be disposed in the upper portion of the semiconductor substrate 100, and the first transfer gate TG1 may be disposed above the semiconductor substrate 100 between the first source-drain region SD1 and the second source-drain region SD2. The third source-drain region SD3 and the fourth source-drain region SD4 may be disposed in the upper portion of the semiconductor substrate 100, and the second transfer gate TG2 may be disposed above the semiconductor substrate 100 between the third source-drain region SD3 and the fourth source-drain region SD4.

While FIG. 1 illustrates an example in which two source-drain regions are disposed on either side of a transfer gate in the second horizontal direction DR2, the example embodiments are not limited thereto. The planar arrangement of the pixel transistors may be varied.

While FIG. 1 illustrates an example in which the pixel PX includes two pixel transistors, a first pixel transistor PTR1 and a second pixel transistor PTR2, in some example embodiments, the pixel PX may include only one pixel transistor. For example, in at least one example embodiment, the pixel PX may include only the first pixel transistor PTR1 and the second pixel transistor PTR2 may be omitted. In another at least one example embodiment, the second pixel transistor PTR2 may be used as a dummy transistor that does not substantially perform the function of a transistor. For example, in at least some cases, a ground voltage may be applied to the second transfer gate TG2 such that the second pixel transistor PTR2 may be always turned off.

The pixel PX may be formed using the semiconductor substrate 100. The semiconductor substrate 100 may have a first surface 100a and a second surface 100b opposite each other. The semiconductor substrate 100 may be a substrate in which the first conductive epitaxial layer is formed on a first conductive (e.g., P-type) bulk semiconductor substrate, and the bulk silicon substrate is removed during the manufacturing process of the image sensor, leaving only the P-type epitaxial layer. Alternatively, the semiconductor substrate 100 may be a bulk semiconductor substrate including wells of the first conductive type. In at least some embodiments, the semiconductor substrate 100 may include an elemental semiconductor and/or a compound semiconductor.

The trench structures 400 and 500 may be disposed in the interior of the semiconductor substrate 100 extending in a vertical direction DR3 from the first surface 100a to the second surface 100b of the semiconductor substrate 100 to electrically and optically isolate the first photoelectric conversion region NRD11 from the second photoelectric conversion region NRD12, included in the first sub-pixel and the second sub-pixel, respectively. The trench structures 400 and 500 may include an inter-pixel trench structure 400 that defines each pixel region and isolates each pixel PX and neighboring pixels, and an intra-pixel trench structure 500 that defines two sub-pixel regions within each pixel region and isolates a first sub-pixel and a second sub-pixel included in each pixel PX from each other.

The inter-pixel trench structures 400 may extend in a vertical direction DR3 from the first surface 100a to the second surface 100b of the semiconductor substrate 100 to surround the periphery of the pixel PX.

The intra-pixel trench structure 500 may be configured to prevent (e.g., block) and/or reduce incident light from crossing between the first photoelectric conversion region NRD11 and the second photoelectric conversion region NRD12 included in the first sub-pixel and the second sub-pixel, respectively, and photo-charges generated by the incident light from being incident into neighboring sub-pixels. In other words, the intra-pixel trench structure 500 may reduce and/or prevent crosstalk between the photoelectric conversion regions NRD11 and NRD12. The inter-pixel trench structure 400 may also reduce and/or prevent crosstalk between each pixel PX and neighboring pixels.

In at least one example embodiment, at least a portion of the center portion CREG of the intra-pixel trench structure 500 in the second horizontal direction DR2 may be removed, as shown in FIG. 5. FIG. 5 illustrates an example in which a portion corresponding to the central region CREG of the intra-pixel trench structures 500 is removed in the vertical direction DR3 from the first surface 100a to the second surface 100b of the semiconductor substrate 100, but the examples are not limited thereto.

The top surface of the trench structures 400 and 500 may be substantially coplanar with the first surface 100a of the semiconductor substrate 100. Additionally, the top surface of the trench structures 400 and 500 may be substantially coplanar with the top surface of the device separator STI.

The trench structures 400 and 500 may be formed of an insulating material with a lower refractive index than the semiconductor substrate 100 and may include one or more insulating films. The trench structures 400 and 500 may include, for example, one or more of a silicon oxide film, a silicon nitride film, an undoped polysilicon film, air, and/or the like. In at least one example embodiment, the trench structures 400 and 500 may include a liner insulation pattern, a semiconductor pattern, and a capping insulation pattern. These trench structures 400 and 500 may be formed by patterning the first surface 100a and/or the second surface 100b of the semiconductor substrate 100 to form deep trenches, and then embedding the liner insulating film and the impurity-doped semiconductor film within the deep trenches. The thickness of the inter-pixel trench structure 400 and the thickness of the intra-pixel trench structure 500 may be the same or may be different.

The first and second photoelectric conversion regions NRD1 and NRD2 may be impurity regions doped with impurities of a second conductivity type (e.g., N-type) opposite to the first conductivity type of the semiconductor substrate 100. Thus, the semiconductor substrate 100 and the first and second photoelectric conversion regions NRD1 and NRD2 may constitute a pair of photodiodes (e.g., a photodiode may be formed by a junction of the semiconductor substrate 100 of the first conductive type and the first or second photoelectric conversion regions NRD1 or NRD2). The first and second photoelectric conversion regions NRD1 and NRD2 including the photodiode may thereby be configured to generate and accumulate photoelectric charges or photo-charges proportional to the intensity of the incident light.

Each of the first and second photoelectric conversion regions NRD1 and NRD2 may have a first length in the first horizontal direction DR1 and a second length in the second horizontal direction DR2, with the second length greater than the first length. For example, in at least some embodiments, the second length may be about twice as long as the first length. As will be described below, the first and second pixel transistors PTR1 and PTR2, which may be utilized as transistors of a readout circuit, may be disposed in a position overlapping in the vertical direction DR3 with the first and second photoelectric conversion regions NRD1 and NRD2. Thus, the integration of the image sensor may be improved by implementing the transistors of the readout circuit within the pixel.

According to some example embodiments, the first and second photoelectric conversion regions NRD1 and NRD2 may be spaced apart from each other in the first horizontal direction DR1 across the intra-pixel trench structure 500. The intra-pixel trench structure 500 may physically reflect incident light from the edges of each pixel region, thereby reducing crosstalk between the first and second photoelectric conversion regions NRD1 and NRD2 in each pixel region.

The device separator STI may be disposed adjacent to the first surface 100a of the semiconductor substrate 100 in each pixel region. A bottom side of the device separator STI may be spaced apart from the first and second photoelectric conversion regions NRD1 and NRD2.

The device separator STI may be provided in a trench formed by recessing the first surface 100a of the semiconductor substrate 100. The device separator STI may be made of an insulating material. In at least one example embodiment, the device separator STI may include a liner oxide film and/or a liner nitride film that conformably cover the surface of the trench, and a buried oxide film that fills the trench in which the liner oxide film and the liner nitride film are formed. The top surface of the device separator STI may be substantially coplanar with the first surface 100a of the semiconductor substrate 100. Further, the top surface of the device separator STI may be substantially coplanar with the top surface of the trench structures 400 and 500.

According to some example embodiments, the device separator STI may define first, second, third, and fourth active portions ACT1, ACT2, ACT3, and ACT4 in each pixel region. From a planar perspective, the first and second active portions ACT1 and ACT2 may overlap with the first photoelectric conversion region NRD1, and the third and fourth active portions ACT3 and ACT4 may overlap with the second photoelectric conversion region NRD2.

In at least one example embodiment, the first active portion ACT1 and the second active portion ACT2 may be separated from each other in the second horizontal direction DR2 by a device separator STI, and may have different sizes and shapes. Further, the third active portion ACT3 and the fourth active portion ACT4 may be spaced apart from each other in the second horizontal direction DR2 by the device separator STI, and may have different sizes and shapes.

The intra-pixel trench structure 500 may be disposed between the first active portion ACT1 and the third active portion ACT3, and between the second active portion ACT2 and the fourth active portion ACT4.

According to some example embodiments, first active portion ACT1 and the third active portion ACT3 may have substantially the same size and shape. According to some example embodiments, the first and third active portions ACT1 and ACT3 are shown in a rectangular shape, but the examples are not limited thereto; and the first and third active portions ACT1 and ACT3 may have polygonal shapes of various geometries.

According to some example embodiments, the second active portion ACT2 and the fourth active portion ACT4 may have substantially the same size and shape. For example, each of the second and fourth active portions ACT2 and ACT4 may have a long axis in the second horizontal direction DR2 and a short axis in the first horizontal direction DR1. Each of the second and fourth active portions ACT2 and ACT4 may have a width in the first horizontal direction DR1 that is less than the width of the first or second photoelectric conversion region NRD1 and NRD2. Further, each of the second and fourth active portions ACT2 and ACT4 may have a length, in the second horizontal direction DR2, that is less than the length of the first and second photoelectric conversion regions NRD1 and NRD2.

A gate insulating layer GOX may be disposed on the semiconductor substrate 100, and gates TG1, TG2, PG1, and PG2 may be disposed on the gate insulating layer GOX. The gate insulating layer GOX may include an insulator, such as an insulating oxide. In at least one example embodiment, as shown in FIGS. 2 and 4, each of the first transfer gate TG1 and the second transfer gate TG2 may be implemented as a combination of a horizontal transfer gate HTG and a vertical transfer gate VTG. The vertical transfer gate VTG may be surrounded by the gate insulating layer GOX. In other example embodiments, each of the first transfer gate TG1 and the second transfer gate TG2 may include only a horizontal transfer gate HTG or only a vertical transfer gate VTG.

As shown in FIG. 1, the pixel PX includes one microlens CMLS shared by the first sub-pixel and the second sub-pixel, and the pixel PX may be a two-photodiode (2PD) pixel for autofocusing. The microlens CMLS may be disposed above or below the semiconductor substrate 100 such that the microlens CMLS may overlap in the vertical direction DR3 with the first photoelectric conversion region NRD1 and the second photoelectric conversion region NRD2 and is configured to focus incident light on the first photoelectric conversion region NRD1 and the second photoelectric conversion region NRD2.

As shown in FIG. 2, the first transfer gate TG1 through which signals such as a transmission control signal TS1 are input and output, and a source-drain region SD2 to which a voltage such as a pixel power voltage Vpix is applied, may be connected to metal lines MPT1 through MPT4 of the metal layer ML via vertical contacts VC1 through VC4. Using these vertical contacts and metal lines, jumper structures JMP1 and JMP2 of FIG. 18 may be formed.

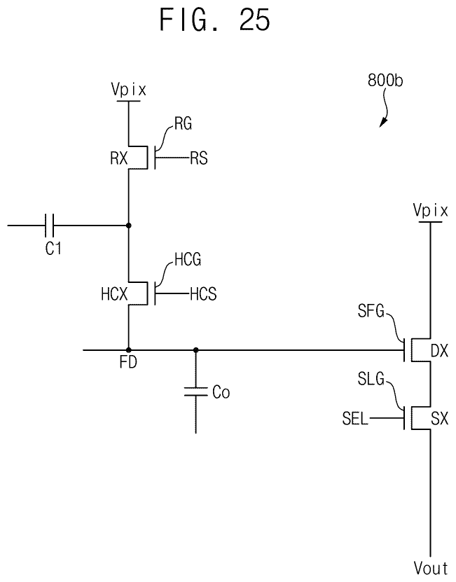

As shown in FIG. 2, the bridge region BR may be disposed below the second source-drain region SD2 to which the pixel power voltage Vpix is applied. The bridge region BR may be configured to form an overflow barrier potential and to discharge redundant photo-charges from the first photoelectric conversion region SD1 and the second photoelectric conversion region SD2 to the second source-drain region SD2. The overflow barrier potential will be further described below with reference to FIG. 25.

In some example embodiments, the pixel power voltage Vpix may be applied to the fourth source-drain region SD4 as well as the second source-drain region SD2. In these cases, the bridge region BR may be disposed below the fourth source-drain region SD4 in addition to the second source-drain region SD2. In this way, at least one overflow path PTH2 of redundant photo-charges distinct from a charge transfer path PTH1 may be provided for each pixel PX.

In at least one example embodiment, as shown in FIGS. 1 and 2, the second source-drain region SD2 with the bridge region BR formed underneath may be a source-drain region disposed more adjacent to the inter-pixel trench structure 400 than the first source-drain region SD1 with the bridge region BR not formed underneath the first source-drain region SD1. As such, the overflow path PTH2 may be formed to the second source-drain region SD2, which is positioned outwardly to be less affected by the voltage applied to the first transfer gate TG1.

For structures where the trench structure penetrates the substrate and the inter-pixel trench structure 400 is closed in an FDTI 2PD pixel containing two photodiodes in a single pixel, electrons accumulating within a pixel may be overflowed and drained through the floating diffusion region. Especially in relatively high intensity situations, such as sun spots, the overflow emissions may be large and may cause sensing errors due to the scattering effect of the dynamic range of the floating diffusion region, where the potential level of the floating diffusion region determines the off potential of the reset transistor. To solve this, the off potential of the reset transistor needs to be designed to be more negative, but the turn-on voltage of the reset transistor needs to be increased to compensate for the hard reset of the reset transistor. In these cases, the headroom margin of the reset level is reduced due to the increased feed-through of the reset transistor. Therefore, a structure that is configured to allow the overflow of the photo-charges that accumulate in the photoelectric conversion region to be drained through a path other than the transfer gate side is beneficial in overcoming this issue.

Thereby, the pixel PX according to the example embodiments may efficiently improve the electrical characteristics of the pixel and image sensor by providing the overflow path PTH2 by adding only the bridge region BR with a relatively simple structure.

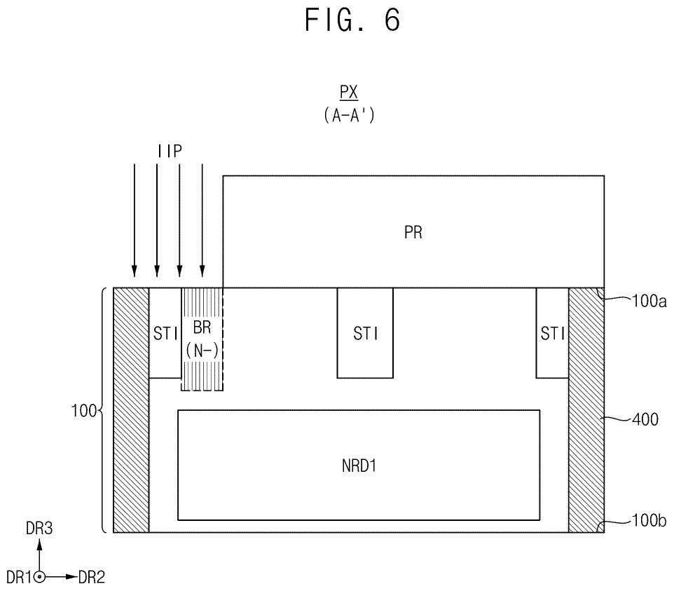

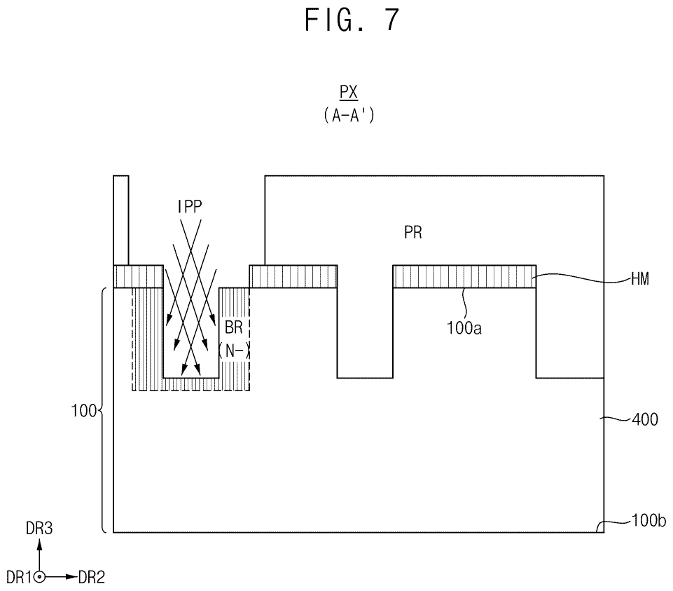

FIGS. 6 and 7 are diagrams illustrating an example of manufacturing a pixel according to some example embodiments. Hereinafter, descriptions redundant with FIGS. 1 through 5 may be omitted for brevity.

Referring to FIG. 6, after forming a device separator STI, a photoresist PR may be formed on a semiconductor substrate 100 and a bridge region BR may be formed by injecting N-type impurities through an ion implantation (IIP) process using the photoresist PR as a mask. Then, a second source-drain region SD2 may be formed at a position that is vertically overlapped with the bridge region BR. In these cases, the second source-drain region SD2 may be doped with an N-type impurity of a first concentration (N+), and the bridge region BR may be doped with an N-type impurity of a second concentration (N−) that is less than the first concentration (N+).

Referring to FIG. 7, after forming the trenches to form the device separator STI using a hard mask HM, a photoresist PR may be formed on the semiconductor substrate 100 and N-type impurities may be injected through a tilted IIP process using the photoresist PR to form a bridge region BR. Subsequently, a second source-drain region SD2 may be formed at a location that is vertically overlapped with the bridge region BR. In this case, the second source-drain region SD2 may be doped with an N-type impurity of a first concentration (N+), and the bridge region BR may be doped with an N-type impurity of a second concentration (N−) that is less than the first concentration (N+).

Through the process described with reference to FIGS. 6 and 7, a bridge region BR may be provided such that the bridge region BR is in contact with the second source-drain region SD2 as shown in FIG. 2 and spaced apart in the vertical direction DR3 from the first photoelectric conversion region NRD1. By such a bridge region BR, the barrier potential of the overflow path PTH2 for discharging the redundant photo-charges may be lowered.

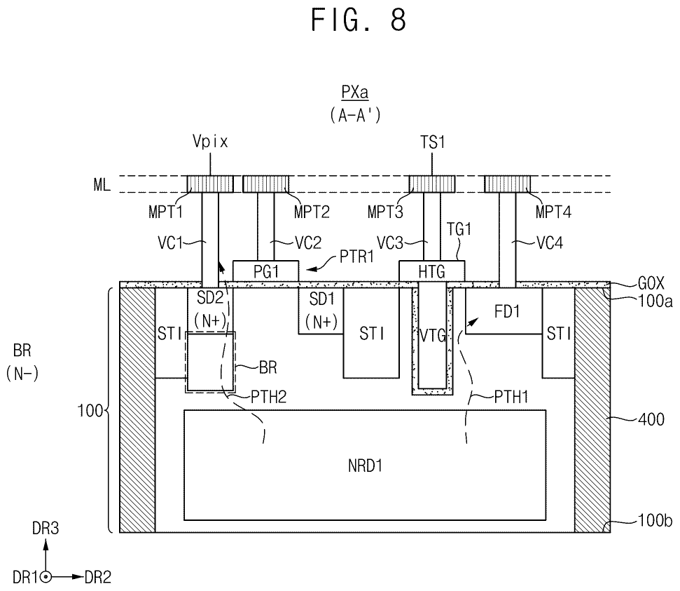

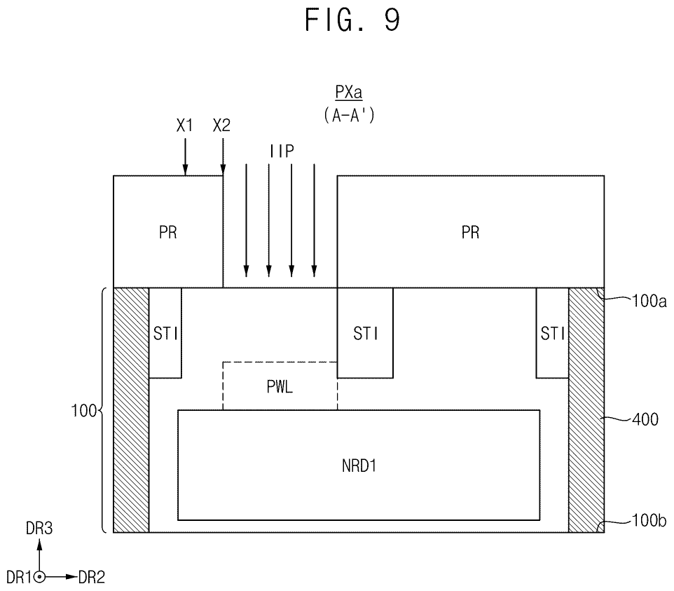

FIG. 8 is a cross-sectional diagram illustrating a pixel according to example embodiments, and FIG. 9 is a diagram illustrating an example embodiment of manufacturing the pixel of FIG. 8. Hereinafter, descriptions redundant with FIGS. 1 through 5 may be omitted.

Referring to FIGS. 8 and 9, a pixel PXa may have bridge region BR that extends a second source-drain region SD2 in the vertical direction DR3 to be deeper than the first source-drain region SD1.

According to some example embodiments, a P-shaped well PWL may be formed by forming a photoresist on the P-shaped semiconductor substrate 100 and injecting impurities through an IIP process using the photoresist PR. The impurity concentration in the p-type wells PWL may be less than the impurity concentration in the semiconductor substrate 100.

As shown in FIG. 9, the conventional position X1 of the photoresist PR may be changed to a different position X2. This results in a weaker concentration of the P-shaped well PWL in the portion where the second source-drain region SD2 is formed. Then, when the process for forming the source-drain regions is performed, the second source-drain region SD2 may be formed deeper than the first source-drain region SD1, as shown in FIG. 8.

As such, the second source-drain region SD2 may extend in the vertical direction DR3 deeper than the first source-drain region SD1, and the portion corresponding to the extended depth of the second source-drain region SD2 may correspond to the bridge region BR.

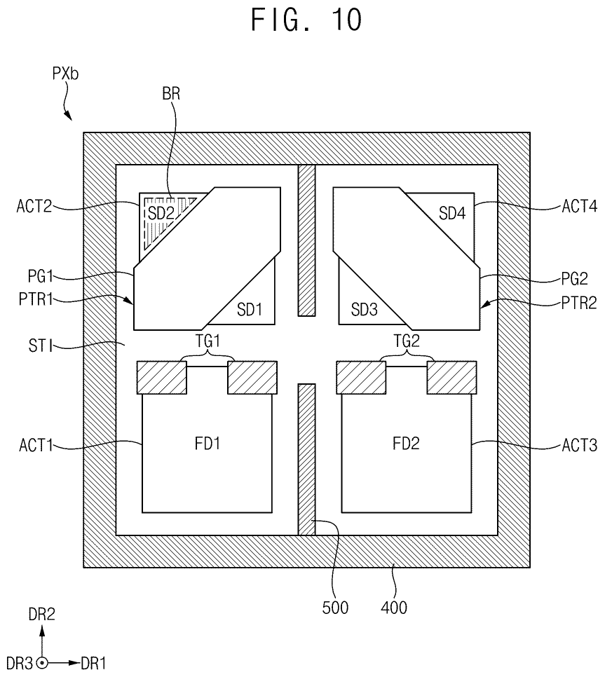

FIGS. 10 through 13 are diagrams illustrating example pixels according to some example embodiments. Hereinafter, descriptions redundant with FIGS. 1 through 5 may be omitted.

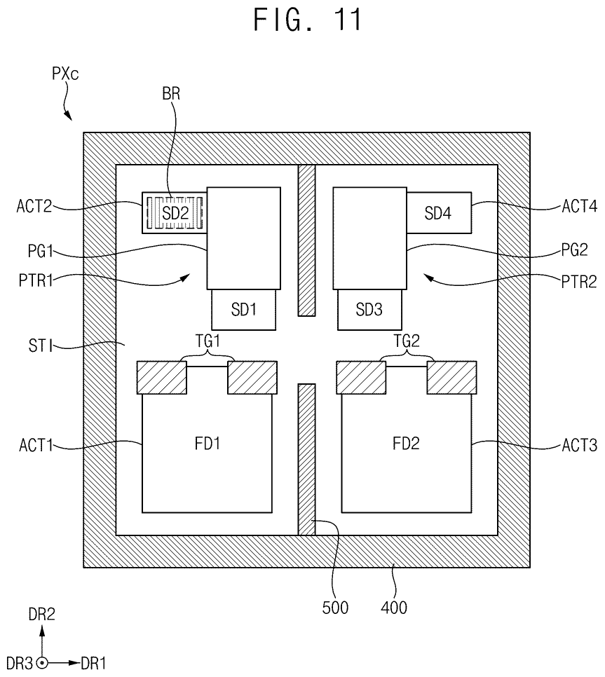

Referring to FIGS. 10 and 11, the planar arrangement of the pixel transistors PTR1 and PTR2 may be varied.

In at least one example embodiment, as shown in FIG. 10, a pixel PXb may have a first pixel gate PG1 and a second pixel gate PG2 each extending in a diagonal direction. A first source-drain region SD1 and a second source-drain region SD2 may be disposed diagonally across the first pixel gate PG1, and a third source-drain region SD3 and a fourth source-drain region SD4 may be disposed diagonally across the second pixel gate PG2. The bridge region BR may be disposed in an outer source-drain region adjacent to the inter-pixel trench structure 400, such as a lower portion of the second source-drain region SD2.

In at least one example embodiment, as shown in FIG. 11, a pixel PXc may be formed such that the two source-drain regions included in each pixel transistor do not face each other. The first source-drain region SD1 may be formed on a side of the second horizontal direction DR2 of the first pixel gate PTR1, the second source-drain region SD2 may be formed on a side of the first horizontal direction DR1 of the first pixel gate PTR1, the third source-drain region SD3 may be formed on a side of the second horizontal direction DR2 of the second pixel gate PTR2, and the fourth source-drain region SD4 may be formed on a side of the first horizontal direction DR1 of the second pixel gate PTR2. A bridge region BR may be disposed in an outlying source-drain region adjacent to the inter-pixel trench structure 400, such as a lower portion of the second source-drain region SD2.

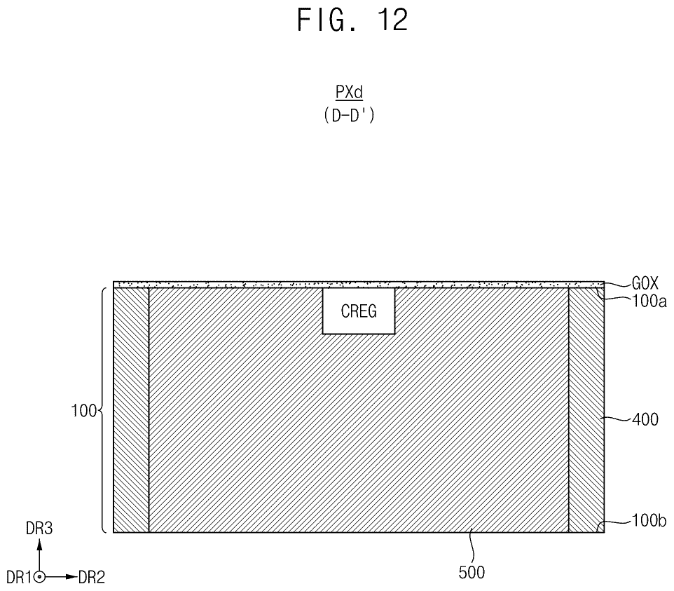

Referring to FIG. 12, a pixel PXd may be partially removed from the first surface 100a of the semiconductor substrate 100 in a portion corresponding to the central region CREG of the intra-pixel trench structure 500. The central region CREG may allow electrons to pass between the two sub-pixels included in the pixel PXd, which may be controlled by the potential profile formed in the semiconductor substrate 100 depending on the length removed and the fabrication process.

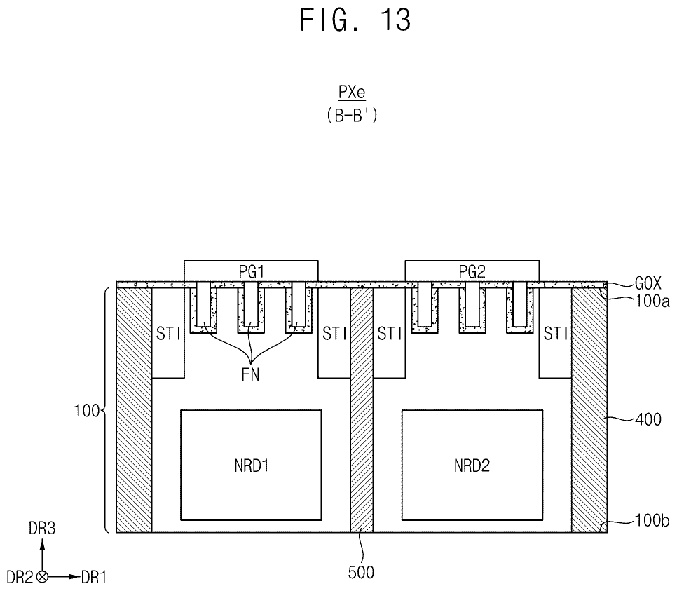

Referring to FIG. 13, a pixel Pxe may have a plurality of fins FNs arranged in a first horizontal direction DR2 penetrating into the interior of the semiconductor substrate 100 at the bottom of the first pixel gate PG1 and the second pixel gate PG2. By employing such a FinFET structure, the turn-on resistance of the pixel transistors PTR1, PTR2 may be reduced.

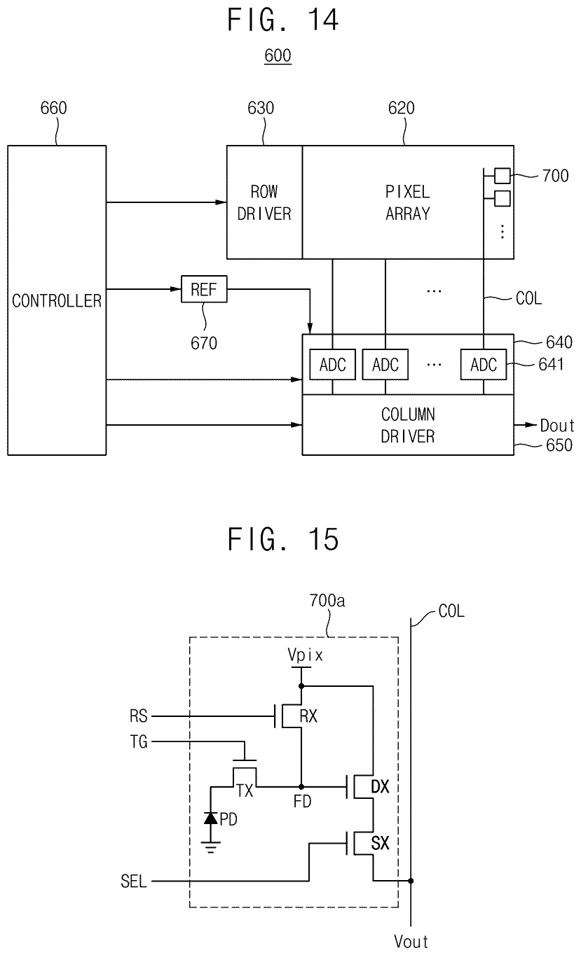

FIG. 14 is a block diagram illustrating an image sensor according to some example embodiments.

Referring to FIG. 14, an image sensor 600 may include a pixel array 620, a row driver 630, an analog-to-digital conversion circuit 640, a column driver 650, a controller 660, and/or a reference signal generator (REF) 670.

The pixel array 620 includes a plurality of pixels 700 coupled to column lines COL, respectively, and the plurality of pixels 700 are configured to sense incident light to generate analog signals through the column lines COL. The plurality of pixels 700 may be arranged in matrix form with a plurality of rows and a plurality of columns. The pixel array 620 may have a structure that various unit patterns, which will be described below with reference to FIGS. 30 through 33, are arranged repeatedly in the first horizontal direction DR1 and the second horizontal direction DR2.

The row driver 630 may be coupled to the rows of the pixel array 620 and may be configured to generate signals for driving the rows. For example, the row driver 630 may drive the pixels in the pixel array 620 row by row.

The analog-to-digital conversion circuit 640 may be coupled to the columns of the pixel array 620 and may be configured to convert the analog signals from the pixel array 20 to digital signals. As illustrated in FIG. 14, the analog-to-digital conversion circuit 640 may include a plurality of analog-to-digital converters (ADC) 641 to perform analog-to-digital conversion of the analog signals output from the column lines COL in parallel or simultaneously.

The analog-to-digital conversion circuit 640 may include a correlated double sampling (CDS) unit. In some example embodiments, the CDS unit may perform an analog double sampling by extracting a valid image component based on a difference between an analog reset signal and an analog image signal. In some example embodiments, the CDS unit may perform a digital double sampling by converting the analog reset signal and the analog image signal to two digital signals and extracting a difference between the two digital signals as the valid image component. In some example embodiments, the CDS unit may perform a dual CDS by performing both the analog double sampling and digital double sampling.

The column driver 650 may be configured to output the digital signals from the analog-to-digital conversion circuit 40 sequentially as output data Dout.

The controller 660 may be configured to control the row driver 30, the analog-to-digital conversion circuit 640, the column driver 650, and/or the reference signal generator 670. The controller 660 may provide control signals such as clock signals, timing control signals, etc. applied to the operations of the row driver 630, the analog-to-digital conversion circuit 640, the column driver 650, and/or the reference signal generator 670. The controller 660 may include a control logic circuit, a phase-locked loop, a timing control circuit, a communication interface circuit, etc.

The reference signal generator 670 may generate a reference signal or a ramp signal that increases or decreases gradually (e.g., with a slope), and provide the ramp signal to the analog-to-digital conversion circuit 40.

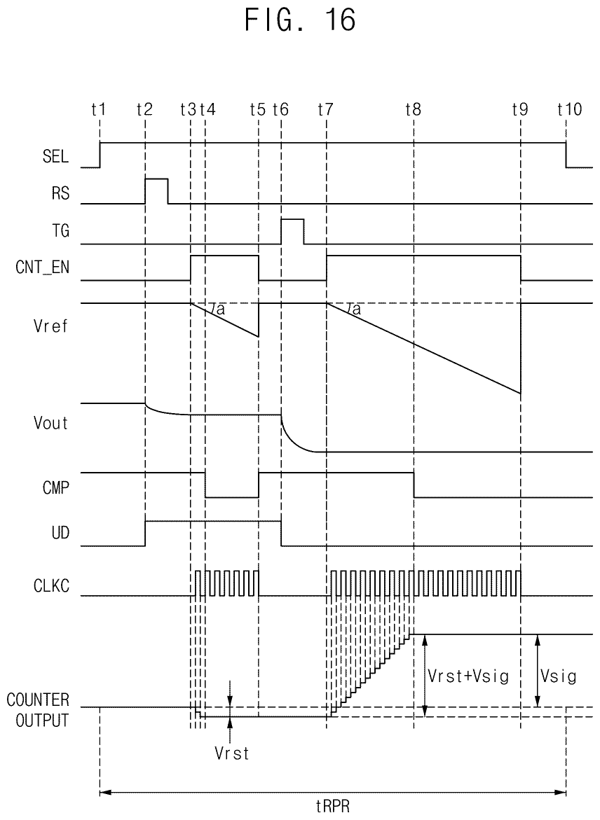

FIG. 15 is a circuit diagram illustrating an example of a unit circuit included in an image sensor according to some example embodiments.

Referring to FIG. 15, a unit pixel 700a may include a photo-sensitive element such as a photodiode PD, and a readout circuit including a transfer transistor TX, a reset transistor RX, a drive transistor DX, and/or a select transistor SX.

For example, the photodiode PD may include an n-type region in a p-type substrate such that the n-type region and the p-type substrate form a p-n conjunction diode. The photodiode PD receives the incident light and generates a photo-charge based on the incident light. In some example embodiments, the unit pixel 600a may include a phototransistor, a photogate, and/or a pinned photodiode, etc. instead of, or in addition to, the photodiode PD.

The photo-charge generated in the photodiode PD may be transferred to a floating diffusion node FD through the transfer transistor TX. The transfer transistor TX may be turned on in response to a transfer control signal TG.

The drive transistor DX is configured to function as a source follower amplifier that amplifies a signal corresponding to the charge on the floating diffusion node FD. The select transistor SX may transfer the pixel signal Vpix to a column line COL in response to a selection signal SEL.

The floating diffusion node FD may be configured to be reset by the reset transistor RX. For example, the reset transistor RX may discharge the floating diffusion node FD in response to a reset signal RS for correlated double sampling (CDS).

FIG. 15 illustrates the unit pixel 700a of the four-transistor configuration including the four transistors TX, RX, DX, and SX. The configuration of the unit pixel may be variously changed, and the pixel structure is not limited to that of FIG. 15.

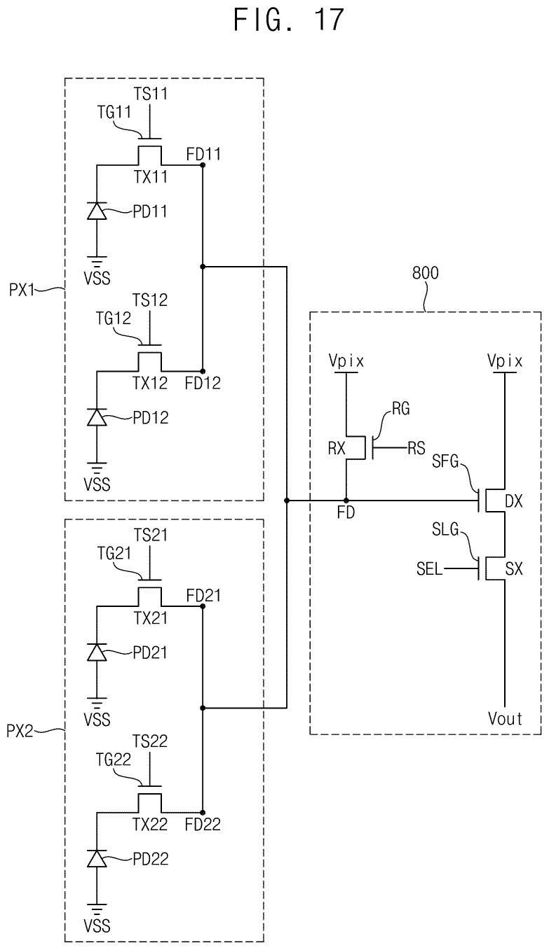

FIG. 16 is a timing diagram illustrating an example operation of an image sensor according to some example embodiments.

FIG. 16 illustrates a sensing period tRPR corresponding to a sensing operation of a pixel. The sensing operation may be performed simultaneously with respect to pixels corresponding to the same transfer control signal TG.

Referring to FIGS. 14, 15, and 16, at a time t1, the row driver 630 may select one of rows included in the pixel array 20 by providing an activated row selection signal SEL to the selected row of the pixel array 620.

At a time t2, the row driver 630 may provide an activated reset control signal RS to the selected row, and the controller 60 may provide an up-down control signal UD having a logic high level to a counter included in the ADC 641. From the time t2, the pixel array 620 may output a first analog signal corresponding to a reset component Vrst as the pixel power voltage Vpix.

At a time t3, the controller 660 may provide a count enable signal CNT_EN having a logic high level to the reference signal generator 670, and the reference signal generator 670 may start to decrease the reference signal Vref at the constant rate, e.g., a slope of ‘a’. The controller 660 may provide a count clock signal CLKC to the counter, and the counters may perform down-counting from zero in synchronization with the count clock signal CLKC.

At a time t4, a magnitude of the reference signal Vref may become smaller than a magnitude of the pixel power voltage Vpix, and a comparator included in the ADC 641 may provide a comparison signal CMP having a logic low level to the counter so that the counter stops performing the down-counting. At the time t4, a counter output of the counter may be the first counting value that corresponds to the reset component Vrst. In the example of FIG. 16, the counter output of the counter at the time t4 may be −2.

At a time t5, the controller 660 may provide the count enable signal CNT_EN having a logic low level to the reference signal generator 670, and the reference signal generator 670 may stop generating the reference signal Vref.

A period from the time t3 to the time t5 corresponds to a maximum time for detecting the reset component Vrst. A length of the period from the time t3 to the time t5 may be determined as a certain number of the count clock signal CLKC according to a characteristic of the image sensor 600.

At a time t6, the row driver 630 may provide an activated transfer control signal TG (e.g., the transfer control signal TG having a logic high level) to the selected row, and the controller 660 may provide the up-down control signal UD having a logic low level to the counter. From the time t6, the pixel array 620 may output a second analog signal AS2 corresponding to a detected incident light Vrst+Vsig as the pixel power voltage Vpix.

At a time t7, the controller 660 may provide the count enable signal CNT_EN having a logic high level to the reference signal generator 670, and the reference signal generator 670 may start to decrease the reference signal Vref at the same constant rate as at the time t3, e.g., a slope of ‘a’. The comparator may provide the comparison signal CMP having a logic high level to the counter since the pixel power voltage Vpix is smaller than the reference signal Vref. The controller 660 may provide the count clock signal CLKC to the counter, and the counter may perform an up-counting from the first counting value, which corresponds to the reset component Vrst, in synchronization with the count clock signal CLKC.

At a time t8, the magnitude of the reference signal Vref may become smaller than the magnitude of the pixel power voltage Vpix, and the comparator may provide the comparison signal CMP having a logic low level to the counter so that the counter stops performing the up-counting. At the time t8, the counter output of the counter may correspond to a difference between the first analog signal representing the reset component Vrst (e.g., −2 in the example of FIG. 16) and the second analog signal representing the detected incident light Vrst+Vsig (e.g., 17 in the example of FIG. 16). The difference may be an effective intensity of incident light Vsig (e.g., 15 in the example of FIG. 16). The counter may output the effective intensity of incident light Vsig as the digital signal.

At a time t9, the controller 660 may provide the count enable signal CNT_EN having a logic low level to the reference signal generator 670, and the reference signal generator 670 may stop generating the reference voltage Vref.

A period from the time t7 to the time t9 corresponds to a maximum time for detecting the detected incident light Vrst+Vsig. A length of the period from the time t7 to the time t9 may be determined as a certain number of the count clock signal CLKC according to a characteristic of the image sensor 600.

At a time t10, the row driver 630 may provide a deactivated row selection signal SEL (e.g., the row selection signal having a low level) to the selected row of the pixel array 620, and the counter may reset the counter output to zero.

After that, the image sensor 600 may repeat the above described operations on each row to generate the digital signals row by row.

However, the example embodiments are not limited to the example configuration and operation described with reference to FIGS. 14, 15, and 16.

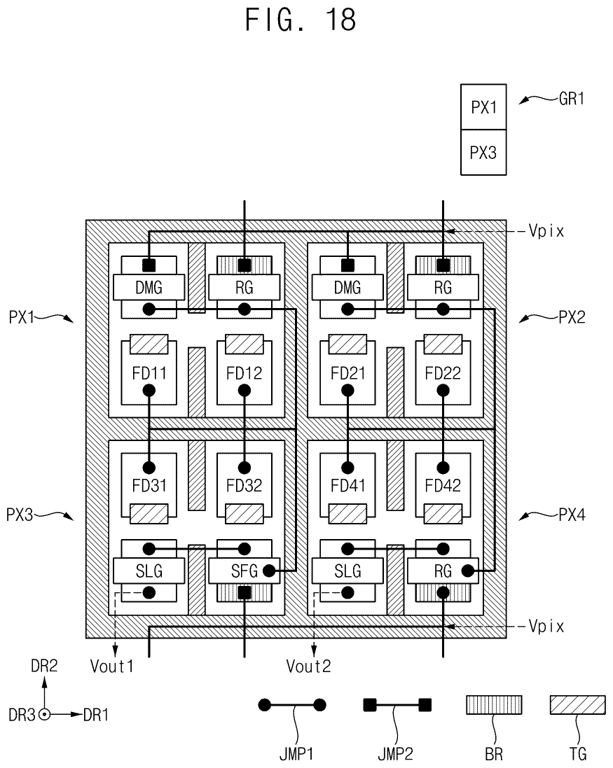

FIG. 17 is a circuit diagram illustrating a configuration of pixels and a readout circuit included in an image sensor according to example embodiments.

Referring to FIG. 17, a first pixel PX1 and a second pixel PX2 may share a single readout circuit 800.

The first pixel PX1 may include a first photodiode PD11, a second photodiode PD12, a first transfer transistor TX11, a second transfer transistor TX12, a first floating diffusion region FD11, and a second floating diffusion region FD12.

The second pixel PX2 may include a third photodiode PD21, a fourth photodiode PD22, a third transfer transistor TX21, a fourth transfer transistor TX22, a third floating diffusion region FD21, and a fourth floating diffusion region FD22.

The first through fourth floating diffusion regions FD11, FD12, FD21, and FD22 may be electrically connected to each other via a jumper structure JMP1 as will be further described below with reference to FIG. 18 to form a common floating diffusion region FD. The common floating diffusion region FD is connected to the gate of the source follower transistor DX, e.g., the source follower gate SFG.

The readout circuit 800 may include a reset transistor RX, a source follower transistor DX, and a select transistor SX. As will be described below, the reset transistor RX, the source follower transistor DX, and the select transistor SX may correspond to pixel transistors included in the first pixel PX1 and the second pixel PX2. VSS denotes the ground voltage and Vpix denotes the pixel power voltage. The reset transistor RX may be connected between a reset voltage (e.g., the pixel power voltage Vpix) and a common floating diffusion region FD, and may be switched in response to a reset signal RS.

Control signals TS11, TS12, TG21, TG22, RG, and SLG provided to the first pixel PX1, the second pixel PX2, and the gates TG11, TG12, TG21, TG22, RG, and SLG of the readout circuit 800 may be provided from the row drive 630 of FIG. 14 via wiring in the row direction, e.g., the first horizontal direction DR1.

While FIG. 17 illustrates a structure in which the readout circuit 800 includes three transistors, the example embodiments are not limiter thereto, and may be adapted to a variety of other configurations.

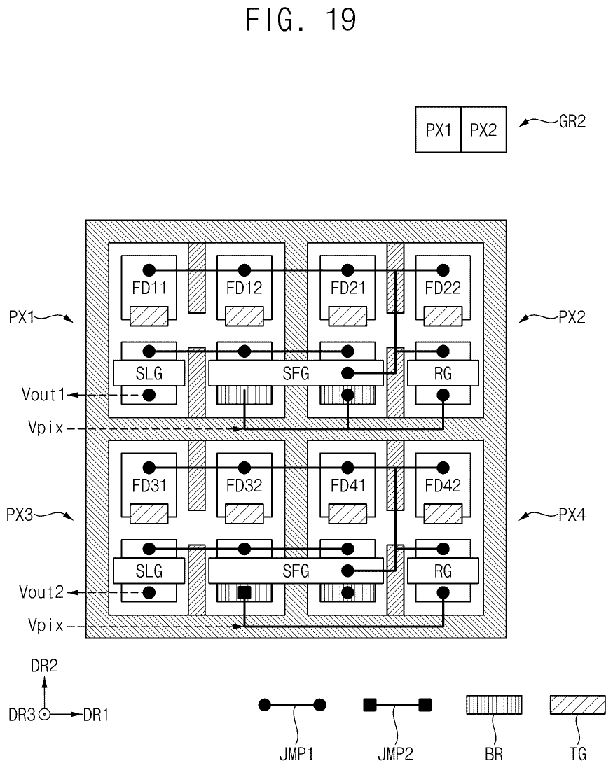

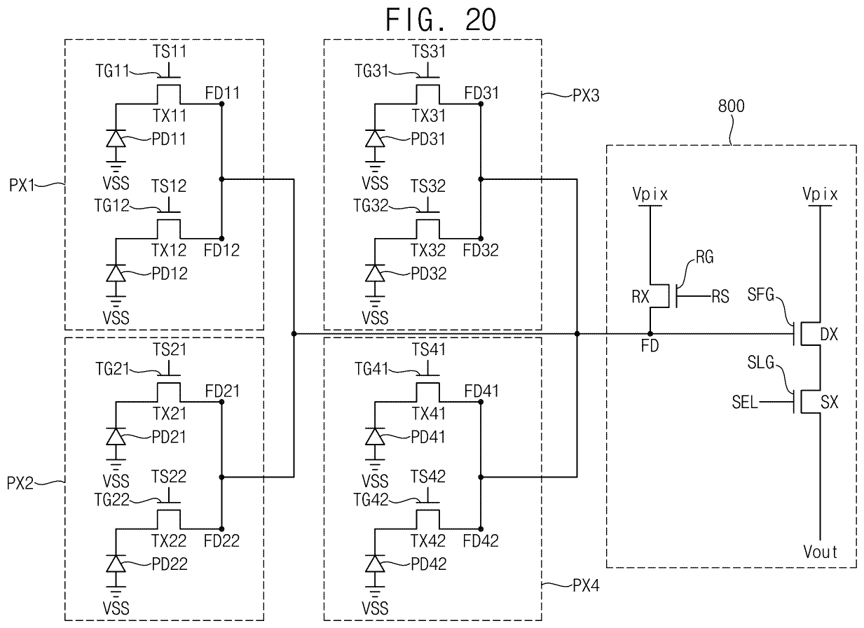

FIGS. 18 and 19 are plan views illustrating some example embodiments of a layout of an image sensor corresponding to the configuration of FIG. 17. Hereinafter, descriptions redundant with FIGS. 1 through 5 may be omitted.

The pixel array of the image sensor includes a plurality of pixels arranged in a matrix form adjacent to each other in the first horizontal direction DR1 and the second horizontal direction DR2. In FIGS. 18 and 19, only the first through fourth pixels PX1, PX2, PX3, and PX4) are shown for convenience of illustration.

The jumper structure JMP1 represents a conductive path connecting the nodes of the pixels to each other, and jumper structure JMP2 represents a conductive path to which the pixel power voltage Vpix is applied. The jumper structures JMP1 and JMP2 may include vertical contacts and metal lines as described with reference to FIG. 2.

As shown in FIGS. 18 and 19, each of the first through fourth pixels PX1, PX2, PX3, and PX4 may include two pixel transistors. DMG denotes a gate of a dummy transistor, RG denotes a gate of a reset transistor, SFG denotes a gate of a source follower transistor, and SLG denotes a gate of a select transistor. The pixels included in each pixel group share a readout circuit including a source follower transistor, a select transistor, and a reset transistor, and the pixel transistors included in each pixel group may be utilized as the source follower transistor, the select transistor, and the reset transistor.

The pixel power voltage Vpix may be applied to the source-drain region of the reset transistor and the source-drain region of the source follower transistor via the jumper structure JMP2. The pixel signals Vout1 and Vou2 corresponding to the pixel group GR1 may be output through the source-drain regions of the select transistors, respectively.

Referring to FIG. 18, two pixels adjacent in the second horizontal direction DR2 may form one pixel group. For example, the first pixel PX1 and the third pixel PX3 may form one pixel group GR1, and the second pixel PX2 and the fourth pixel PX4 may form one (e.g., another) pixel group GR1. These pixel groups GR1 may be repeatedly arranged in the first horizontal direction DR1 and the second horizontal direction DR2.

The four floating diffusion regions FD11, FD12, FD31, and FD32 of the first pixel PX1 and the third pixel PX3 included in the same pixel group GR1 are connected to each other via the jumper structure JMP1. Similarly, the floating diffusion areas FD21, FD22, FD41, and FD42 of the second pixel PX2 and the fourth pixel PX4 included in the same pixel group GR1 are connected to each other via the jumper structure JMP1.

Referring to FIG. 19, two pixels adjacent in the first horizontal direction DR1 may form one pixel group, e.g., the first pixel PX1 and the second pixel PX2 may form one pixel group GR2, and the third pixel PX3 and the fourth pixel PX4 may form one (e.g., another) pixel group GR2. These pixel groups GR2 may be repeatedly arranged in the first horizontal direction DR1 and the second horizontal direction DR2.

The four floating diffusion regions FD11, FD12, FD21, and FD22 of the first pixel PX1 and the second pixel PX2 included in the same pixel group GR2 are connected to each other via the jumper structure JMP1. Similarly, the floating diffusion regions FD31, FD32, FD41, and FD42 of the third pixel PX3 and the fourth pixel PX4 included in the same pixel group GR2 are connected to each other via the jumper structure JMP1.

As described above, a bridge region BR may be formed below the source-drain region to which the pixel power voltage Vpix is applied. FIGS. 18 and 19 illustrate, but are not limited to, an example embodiment in which each of the first through fourth pixels PX1, PX2, PX3, and PX4 includes one bridge region BR. In some example embodiments, some pixels may include two bridge regions BR.

FIG. 20 is a circuit diagram illustrating a configuration of pixels and a readout circuit included in an image sensor according to some example embodiments.

Referring to FIG. 20, a first pixel PX1, a second pixel PX2, a third pixel PX3, and a fourth pixel PX4 may share a single readout circuit 800.

The first pixel PX1 may include a first photodiode PD11, a second photodiode PD12, a first transfer transistor TX11, a second transfer transistor TX12, a first floating diffusion region FD11, and a second floating diffusion region FD12.

The second pixel PX2 may include a third photodiode PD21, a fourth photodiode PD22, a third transfer transistor TX21, a fourth transfer transistor TX22, a third floating diffusion region FD21, and a fourth floating diffusion region FD22.

The third pixel PX3 may include a fifth photodiode PD31, a sixth photodiode PD32, a fifth transfer transistor TX31, a sixth transfer transistor TX32, a fifth floating diffusion region FD31, and a sixth floating diffusion region FD32.

The fourth pixel PX4 may include a seventh photodiode PD41, an eighth photodiode PD42, a seventh transfer transistor TX41, an eighth transfer transistor TX42, a seventh floating diffusion region FD41, and an eighth floating diffusion region FD42.

The first through eighth floating diffusion regions FD11, FD12, FD21, FD22, FD31, FD32, FD41, and FD42 may be electrically connected to each other via the jumper structures JMP1 to form a common floating diffusion region FD. The common floating diffusion region FD is connected to a gate of the source follower transistor DX, e.g., a source follower gate (SFG).

The readout circuit 800 may include a reset transistor RX, a source follower transistor DX, and a select transistor SX. As will be described below, the reset transistor RX, the source follower transistor DX, and the select transistor SX may correspond to pixel transistors included in the first pixel PX1, the second pixel PX2, the third pixel PX3, and the fourth pixel PX4. VSS denotes the ground voltage and Vpix denotes the pixel power voltage. The reset transistor RX may be connected between a reset voltage (e.g., the pixel power voltage Vpix) and the common floating diffusion region FD, and may be switched in response to a reset signal RS.

Control signals TS11, TS12, TG21, TG22, TG31, TG32, TG41, TG42, RG, and SLG provided to the first pixel PX1, the second pixel PX2, the third pixel PX3, the fourth pixel PX4, and the gates TG11, TS12, TS21, TS22, TS31, TS32, TS31, TS42, RS, and SEL may be provided from the row drive 630 of FIG. 14 via wiring in the row direction, e.g., the first horizontal direction DR1.

While FIG. 20 illustrates a structure in which the readout circuit 800 includes three transistors, it will be appreciated that the example embodiments may be adapted to a variety of other configurations.

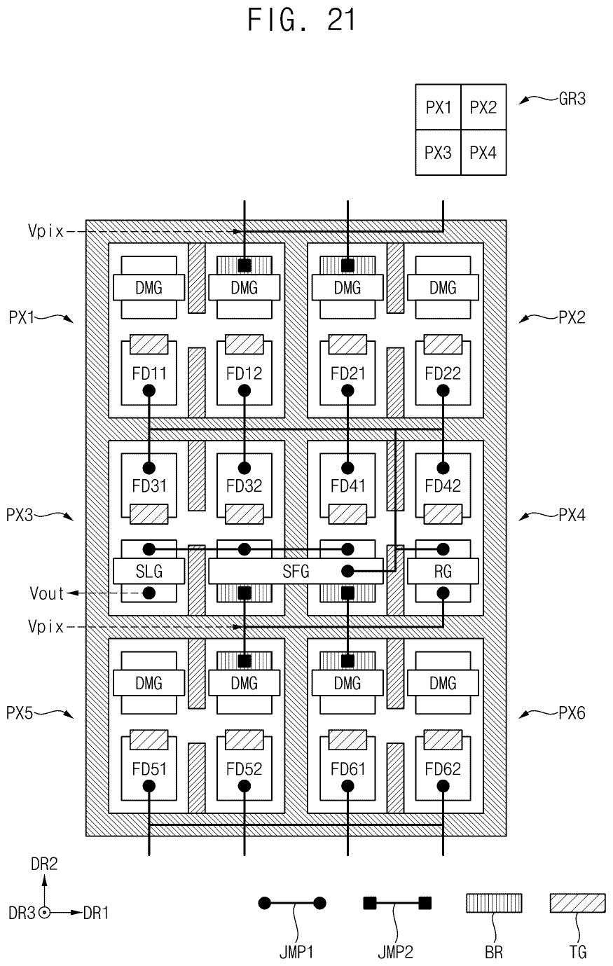

FIG. 21 is a plan view illustrating an example of a layout of an image sensor corresponding to the configuration of FIG. 20 according to some example embodiments. Hereinafter, descriptions redundant with FIGS. 1 through 5 and FIGS. 17 through 19 may be omitted.

The pixel array of the image sensor includes a plurality of pixels arranged in a matrix form adjacent to each other in a first horizontal direction DR1 and a second horizontal direction DR2. In FIG. 21, only the first through sixth pixels PX1, PX2, PX3, PX4, PX5, and PX6 are illustrated for convenience of illustration.

As shown in FIG. 21, each of the first through sixth pixels PX1, PX2, PX3, PX4, PX5, and PX6 may include two pixel transistors. DMG denotes the gate of the dummy transistor, RG denotes the gate of the reset transistor, SFG denotes the gate of the source follower transistor, and SLG denotes the gate of the select transistor. The pixels included in each pixel group share a readout circuit including a source follower transistor, a select transistor, and a reset transistor, and the pixel transistors included in each pixel group may be utilized as the source follower transistor, the select transistor, and the reset transistor.

The pixel power voltage Vpix may be applied to the source-drain region of the reset transistor and the source-drain region of the source follower transistor through the jumper structure JMP2. A pixel signal Vout corresponding to the pixel group GR3 may be output through the source-drain region of the select transistor.

Referring to FIG. 21, four pixels adjacent in the first horizontal direction DR1 and the second horizontal direction DR2 may form one pixel group. That is, the first pixel PX1, the second pixel PX2, the third pixel PX3, and the fourth pixel PX4 may form one pixel group GR3. These pixel groups GR3 may be repeatedly arranged in the first horizontal direction DR1 and the second horizontal direction DR2. Eight floating diffusion regions FD11, FD12, FD21, FD22, FD31, FD32, FD41, and FD42 of the first pixel PX1, the second pixel PX2, the third pixel PX3, and the fourth pixel PX4 included in the same pixel group GR3 are connected to each other through the jumper structures JMP1. In at least one example embodiment, each of the jumper structures JMP1 and JMP2 may be additionally connected to source-drain regions of dummy transistors. As the number of source-drain regions of the dummy transistors connected to the jumper structure increases, the capacitance of the corresponding node may increase. The number of source-drain regions of the dummy transistors connected to the jumper structure may be appropriately adjusted to implement an appropriate capacitance of the corresponding node. In addition, a bridge region BR as described above may be arranged below the source-drain region of the dummy transistor to which the pixel power voltage Vpix is applied.

In at least one example embodiment, as illustrated in FIG. 21, the gate SFG of the source follower transistor may be integrally formed by connecting two pixel gates, one of which is included in each of two pixels PX3 and PX4 adjacent to each other in the first horizontal direction DR1.

As described above, a bridge region BR may be formed below the source-drain region to which the pixel power voltage Vpix is applied. FIG. 21 illustrates an example embodiment in which each of the first through sixth pixels PX1, PX2, PX3, PX4, PX5, and PX6 includes one bridge region BR, but the examples are not limited thereto. According to example embodiments, some pixels may include two bridge regions BR.

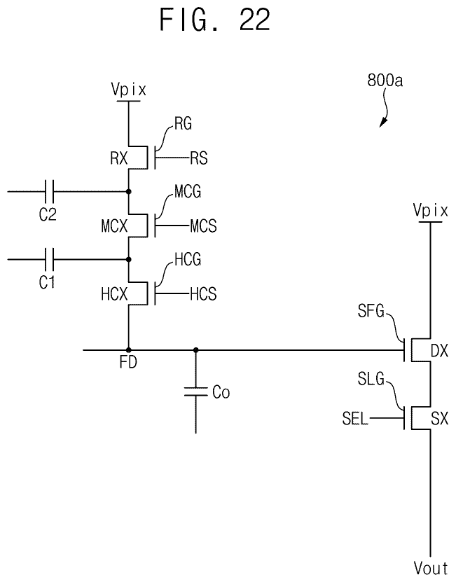

FIG. 22 is a circuit diagram illustrating a configuration of a readout circuit included in an image sensor according to example embodiments. Hereinafter, descriptions redundant with those of FIG. 17 may be omitted.

Referring to FIG. 22, a readout circuit 800a may include a reset transistor RX, a medium gain transistor MCX, a high gain transistor HCX, a source follower transistor DX, and a select transistor SX. Parasitic capacitances Co, C1, and C2 of some nodes are also illustrated in FIG. 22. As will be described below, the reset transistor RX, the medium gain transistor MCX, the high gain transistor HCX, the source follower transistor DX, and the select transistor SX may correspond to pixel transistors included in the first through fourth pixels PX1, PX2, PX3, and PX4. The reset transistor RX, the medium gain transistor MCX, and the high gain transistor HCX are connected in series between a reset voltage (e.g., the pixel power voltage Vpix) and a common floating diffusion region FD, and may be switched in response to a reset signal RS, a medium gain control signal MCS, and a high gain control signal HCS applied to the gates RG, MCG, and HCG, respectively. When the reset transistor RX, the medium gain transistor MCX, and the high gain transistor HCX are turned on, the pixel power voltage Vpix is transferred to the floating diffusion region FD, and accordingly, charges accumulated in the floating diffusion region FD are discharged, such that the floating diffusion region FD may be reset. The medium gain transistor MCX and the high gain transistor HCX may vary the conversion gain of the pixel by varying the capacitance of the floating diffusion region FD in response to the medium gain control signal MCS and the high gain control signal HCS. As the capacitance of the floating diffusion region FD increases, the conversion gain of the pixel may decrease.

When capturing an image, lights of lower luminance, medium luminance, and higher luminance may be incident on the pixel array.

In lower illumination, the reset transistor RX, the medium gain transistor MCX, and the high gain transistor HCX may all be turned off. At this time, the capacitance of the floating diffusion region FD may correspond to Co.

In medium illumination, the reset transistor RX and the medium gain transistor MCX may be turned off, and the high gain transistor HCX may be turned on. At this time, the capacitance of the floating diffusion region FD may correspond to Co+C1.

In higher illumination, the reset transistor RX may be turned off, and the medium gain transistor MCX and the high gain transistor HCX may be turned on. At this time, the capacitance of the floating diffusion region FD may correspond to Co+C1+C2.

As a result, a triple conversion gain TCG may be implemented through selective switching of the medium gain transistor MCX and the high gain transistor HCX.

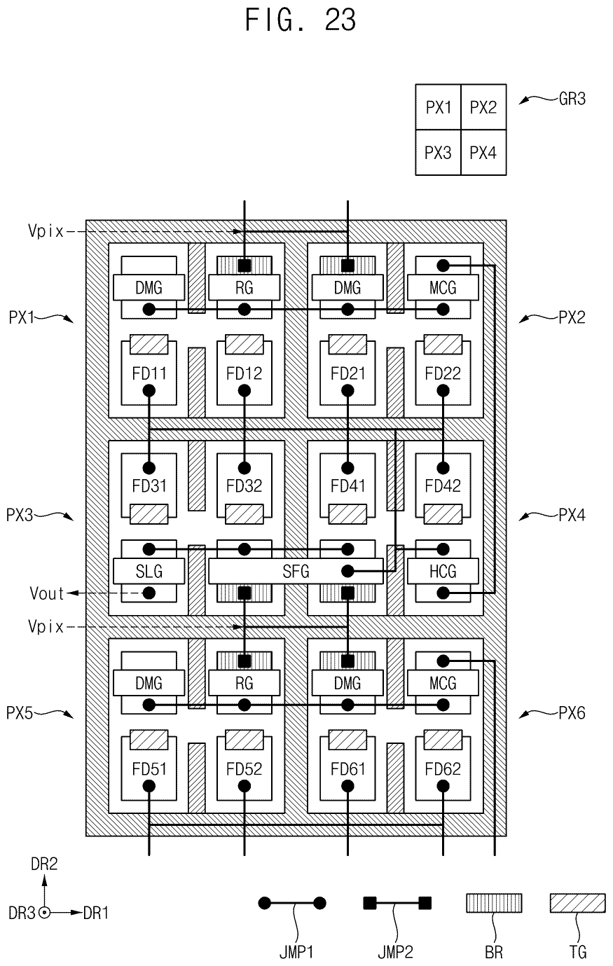

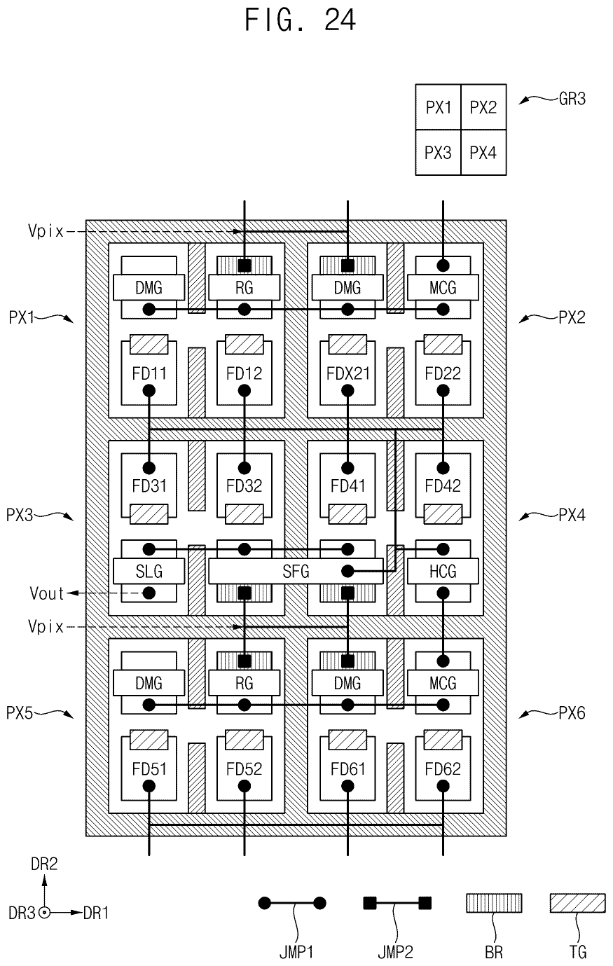

FIGS. 23 and 24 are plan views illustrating example embodiments of a layout of an image sensor corresponding to the configuration of FIG. 22. Hereinafter, descriptions redundant with FIGS. 1 through 5, 20, and 21 may be omitted.

The pixel array of the image sensor includes a plurality of pixels arranged in a matrix form adjacent to each other in a first horizontal direction DR1 and a second horizontal direction DR2. For convenience of illustration, only the first through sixth pixels PX1, PX2, PX3, PX4, PX5, and PX6 are illustrated in FIGS. 23 and 24.

As illustrated in FIGS. 23 and 24, each of the first through sixth pixels PX1, PX2, PX3, PX4, PX5, and PX6 may include two pixel transistors. DMG represents the gate of a dummy transistor, RG represents the gate of a reset transistor, MCG represents the gate of a medium gain transistor, HCG represents the gate of a high gain transistor, SFG represents the gate of a source follower transistor, and SLG represents the gate of a select transistor. The pixels included in each pixel group share a readout circuit including a source follower transistor, a select transistor, a reset transistor, a medium gain transistor, and a high gain transistor, and the pixel transistors included in each pixel group may be used as the source follower transistor, the select transistor, the reset transistor, the medium gain transistor, and the high gain transistor. Referring to FIGS. 23 and 24, four pixels adjacent in the first horizontal direction DR1 and the second horizontal direction DR2 may form one pixel group. That is, the first pixel PX1, the second pixel PX2, the third pixel PX3, and the fourth pixel PX4 may form one pixel group GR3. These pixel groups GR3 may be arranged repeatedly in the first horizontal direction DR1 and the second horizontal direction DR2.

In at least one example embodiment, all of the readout circuit may be included in a single pixel group. For example, as illustrated in FIG. 23, the readout circuits RG, MCG, HCG, SFG, and SLG corresponding to the pixel group GR3 of the first through fourth pixels PX1, PX2, PX3, and PX4 may be implemented using the pixel transistors of the first through fourth pixels PX1, PX2, PX3, and PX4.

In at least one example embodiment, at least a portion of the readout circuit may be included in another adjacent pixel group. For example, as illustrated in FIG. 24, among the readout circuits RG, MCG, HCG, SFG, and SLG corresponding to the pixel group GR3 of the first through fourth pixels PX1, PX2, PX3, and PX4, the gates RG and MCG of the reset transistor and the medium gain transistor may be implemented using the pixel transistors of the fifth pixel PX5 and the sixth pixel PX6.

FIG. 25 is a circuit diagram illustrating a configuration of a readout circuit included in an image sensor according to example embodiments. Hereinafter, any description redundant with FIG. 17 may be omitted.

Referring to FIG. 25, a readout circuit 800a may include a reset transistor RX, a high gain transistor HCX, a source follower transistor DX, and a select transistor SX. FIG. 25 also illustrates parasitic capacitances Co and C1 of some nodes. As will be described below, the reset transistor RX, the medium gain transistor MCX, the high gain transistor HCX, the source follower transistor DX, and the select transistor SX may correspond to pixel transistors included in the first through fourth pixels PX1, PX2, PX3, and PX4. The reset transistor RX and the high gain transistor HCX may be connected in series between a reset voltage (e.g., the pixel power voltage Vpix) and a common floating diffusion region FD, and may be switched in response to a reset signal RS and a high gain control signal HCS applied to the gates RG and HCG, respectively.

When the reset transistor RX and the high gain transistor HCX are turned on, the pixel power voltage Vpix is transferred to the floating diffusion region FD, and accordingly, charges accumulated in the floating diffusion region FD are discharged, such that the floating diffusion region FD may be reset. The high gain transistor HCX may vary the conversion gain of the pixel by varying the capacitance of the floating diffusion region FD in response to the high gain control signal HCS. As the capacitance of the floating diffusion region FD increases, the conversion gain of the pixel may decrease.

When capturing an image, lights of low luminance, medium luminance, and high luminance may be incident on the pixel array.

In lower illumination, both the reset transistor RX and the high gain transistor HCX may be turned off. At this time, the capacitance of the floating diffusion region FD may correspond to Co.

In higher illumination, the reset transistor RX may be turned off and the high gain transistor HCX may be turned on. At this time, the capacitance of the floating diffusion region FD may correspond to Co+C1.

As a result, a double conversion gain DCG may be implemented through selective switching of the high gain transistor HCX.

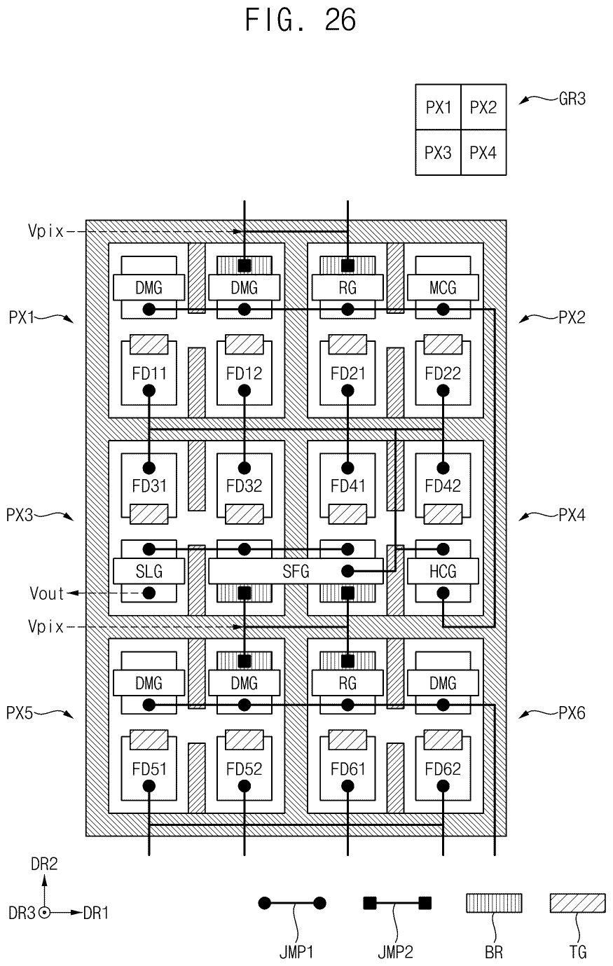

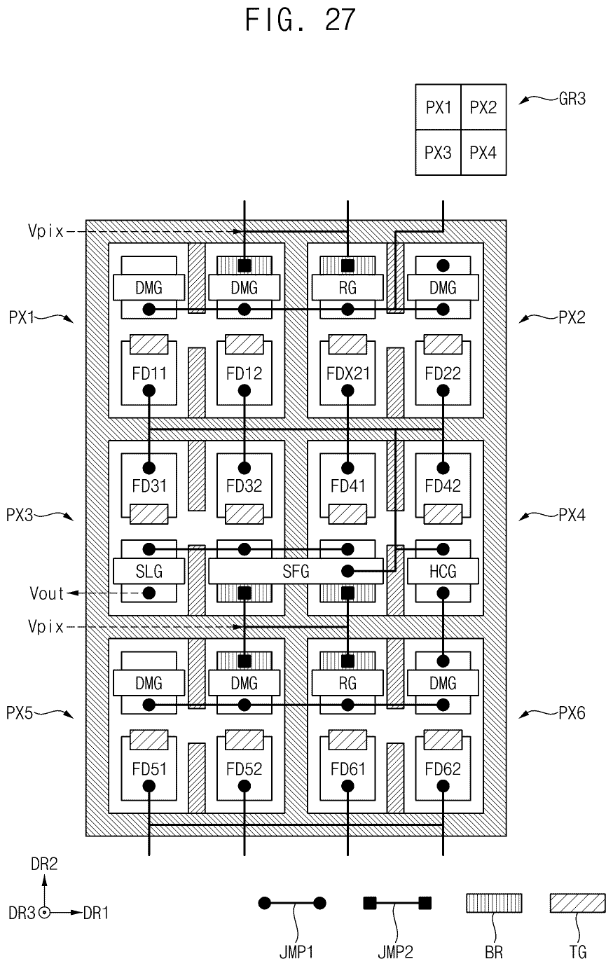

FIGS. 26 and 27 are plan views illustrating examples of a layout of an image sensor corresponding to the configuration of FIG. 25 according to some example embodiments. Hereinafter, descriptions redundant with FIGS. 1 through 5, 20, and 21 may be omitted.

A pixel array of an image sensor includes a plurality of pixels arranged in a matrix form adjacent to each other in a first horizontal direction DR1 and a second horizontal direction DR2. For convenience of illustration, only the first through sixth pixels PX1, PX2, PX3, PX4, PX5, and PX6 are illustrated in FIGS. 26 and 27.

As illustrated in FIGS. 26 and 27, each of the first through sixth pixels PX1, PX2, PX3, PX4, PX5, and PX6 may include two pixel transistors. DMG represents the gate of a dummy transistor, RG represents the gate of a reset transistor, HCG represents the gate of a high gain transistor, SFG represents the gate of a source follower transistor, and SLG represents the gate of a select transistor. The pixels included in each pixel group share a readout circuit including a source follower transistor, a select transistor, a reset transistor, and a high gain transistor, and the pixel transistors included in each pixel group may be used as the source follower transistor, the select transistor, the reset transistor, and the high gain transistor. Referring to FIGS. 26 and 27, four pixels adjacent in the first horizontal direction DR1 and the second horizontal direction DR2 may form one pixel group. That is, the first pixel PX1, the second pixel PX2, the third pixel PX3, and the fourth pixel PX4 may form one pixel group GR3. These pixel groups GR3 may be arranged repeatedly in the first horizontal direction DR1 and the second horizontal direction DR2.

In at least one example embodiment, all of the readout circuit may be included in their own pixel groups. For example, as illustrated in FIG. 26, the readout circuits RG, HCG, SFG, and SLG corresponding to the pixel groups GR3 of the first through fourth pixels PX1, PX2, PX3, and PX4 may be implemented using the pixel transistors of the first through fourth pixels PX1, PX2, PX3, and PX4.

In at least one example embodiment, at least a portion of the readout circuit may be included in another adjacent pixel group. For example, as illustrated in FIG. 27, among the readout circuits RG, MCG, HCG, SFG, and SLG corresponding to the pixel group GR3 of the first through fourth pixels PX1, PX2, PX3, and PX4, the gate RG of the reset transistor may be implemented using the pixel transistor of the sixth pixel PX6.

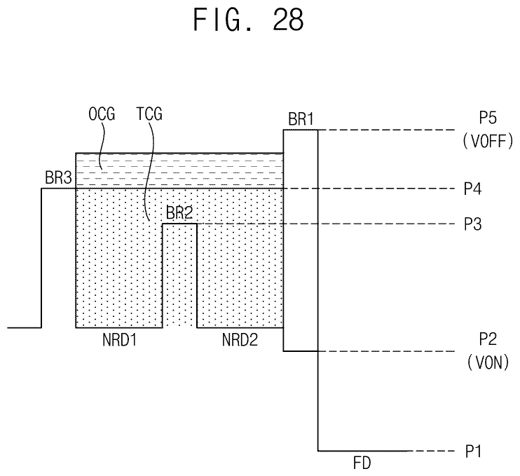

FIG. 28 is a diagram illustrating overflow of a pixel according to some example embodiments.

In FIG. 28, BR1 represents a transfer barrier potential of the charge transfer path PTH1 of FIG. 2 between the photoelectric conversion regions NRD1 and NRD2 and the floating diffusion region FD, BR2 represents an intra-barrier potential between the photoelectric conversion regions NRD1 and NRD2, and BR3 represents an overflow barrier potential of an overflow path PTH2 of FIG. 2 including the bridge region BR described above. P1 represents a reset potential of a floating diffusion region FD, P2 represents a potential when a turn-on voltage VON is applied to a transfer gate, P3 represents an intra-barrier potential BR2, P4 represents an overflow barrier potential BR3, and P5 represents a potential when a turn-off voltage VOFF is applied to the transfer gate. Referring to FIGS. 1 through 5 and 28, the overflow barrier potential P4 may be lower than the transfer barrier potential P5 between the first photoelectric conversion region NRD1 and the first floating diffusion region FD1 when the turn-off voltage VOFF is applied to the first transfer gate TG1. In this case, the redundant photo-charges OCG exceeding the maximum transfer photo-charge TCG may be discharged through the overflow path PTH2 prior to the charge transfer path PTH1.

In addition, the overflow barrier potential P4 may be higher than the intra-barrier potential P3 between the first photoelectric conversion region NRD1 and the second photoelectric conversion region NRD2. In this case, even if the bridge region BR is arranged in only one of the two sub-pixels included in the pixel PX, the redundant photo-charges OCG generated in the first photoelectric conversion region NRD1 and the second photoelectric conversion region NRD2 may all be discharged.

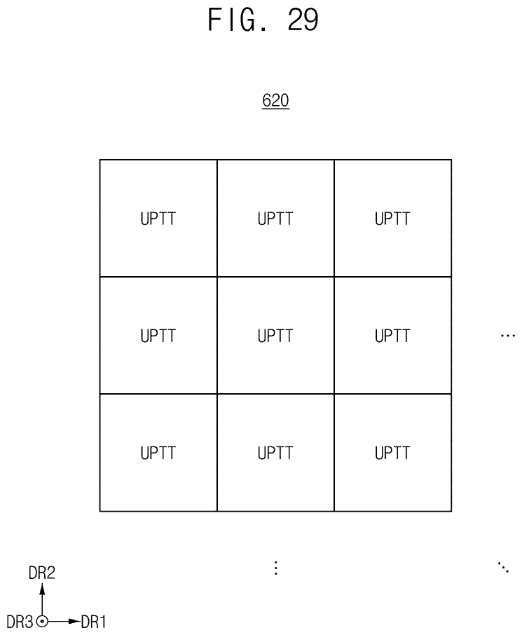

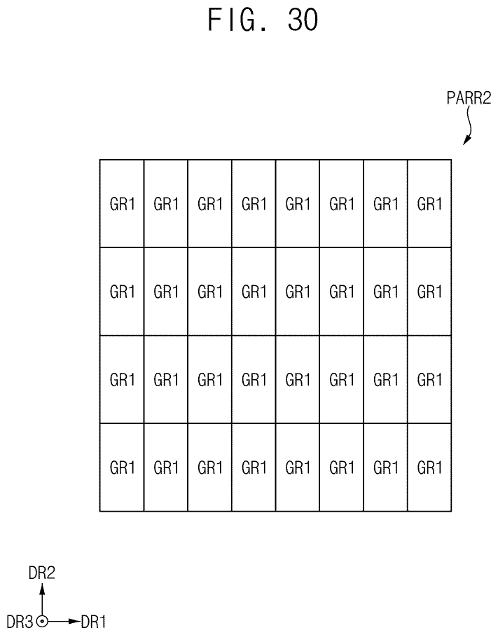

FIG. 29 is a diagram illustrating a layout of a pixel array included in an image sensor according to some example embodiments.

Referring to FIG. 29, the pixel array 620 in the image sensor 600 of FIG. 14 may be divided into unit patterns UPTT that are arranged repeatedly in the first horizontal direction DR1 and the second horizontal direction DR2. Each unit pattern UPTT may include two or more pixel group where each pixel group includes one or more pixels as described above.

In some example embodiments, all of the unit patterns UPTT in the pixel array 620 may be identical and/or substantially similar. In some example embodiments, the unit pattern UPTT is a minimum pattern that cannot be divided into smaller patterns. In some example embodiments, the unit patterns UPTT in the pixel array 620 may include two or more different patterns such that the different patterns are arranged regularly in the first horizontal direction DR1 and/or the second horizontal direction DR2.

Referring now to FIGS. 30 through 33, example embodiments of unit patterns corresponding to various different pixel groups will be described. Depending on example embodiments, the pixel arrays described herein may be inverted in the first horizontal direction DR1 and/or the second horizontal direction DR2 and/or rotated about a vertical direction DR3 by 90 degrees or 180 degrees.

FIGS. 30 through 33 are plan views illustrating examples of an arrangement pattern of a pixel array included in an image sensor according to some example embodiments.

Referring to FIG. 30, the pixel group GR1 of FIG. 18 may correspond to the unit pattern UPTT, and the pixel array may include the pixel groups GR1 that are repeatedly arranged in the first horizontal direction DR1 and the second horizontal direction DR2.

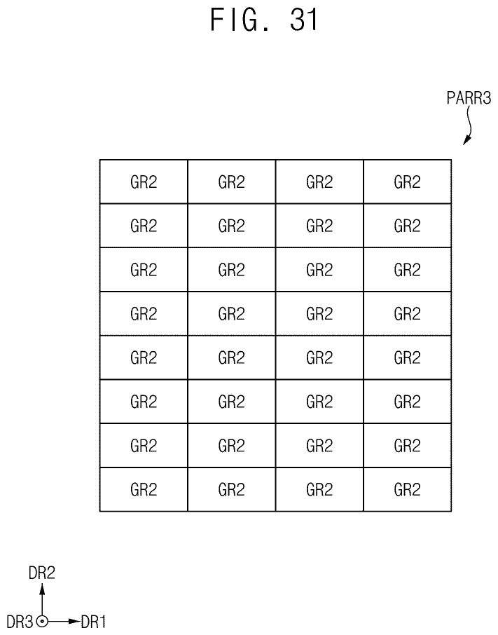

Referring to FIG. 31, the pixel group GR2 of FIG. 19 may correspond to the unit pattern UPTT, and the pixel array may include the pixel groups GR2 that are repeatedly arranged in the first horizontal direction DR1 and the second horizontal direction DR2.

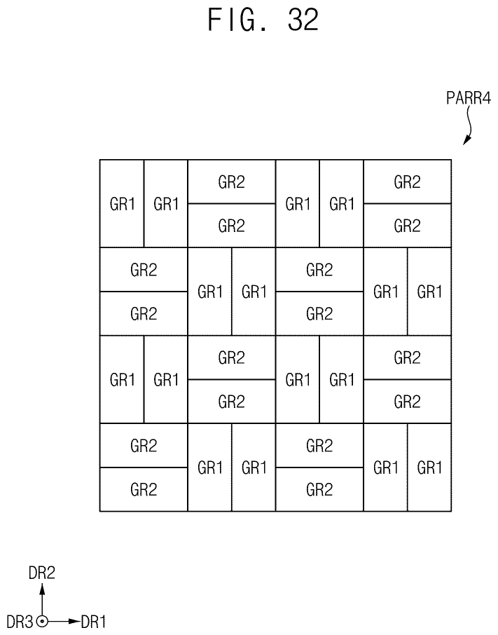

Referring to FIG. 32, the pixel group GR1 of FIG. 18 and the pixel group GR2 of FIG. 19 form a pair, and the pixel array may include a pair of two pixel groups GR1 and a pair of two pixel groups GR2 that are alternately arranged in the first horizontal direction DR1 and the second horizontal direction DR2. In this case, a set of four pixel groups GR1 and four pixel groups GR2 forming a square shape corresponds to the unit pattern UPTT.

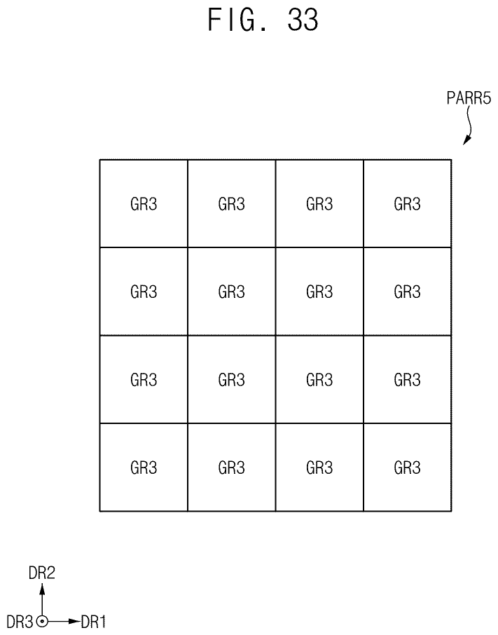

Referring to FIG. 33, pixel groups GR3 of FIGS. 21, 23, 24, 16, and 27 correspond to the unit pattern UPTT, and the pixel array may include pixel groups GR3 that are repeatedly arranged in the first horizontal direction DR1 and the second horizontal direction DR2.

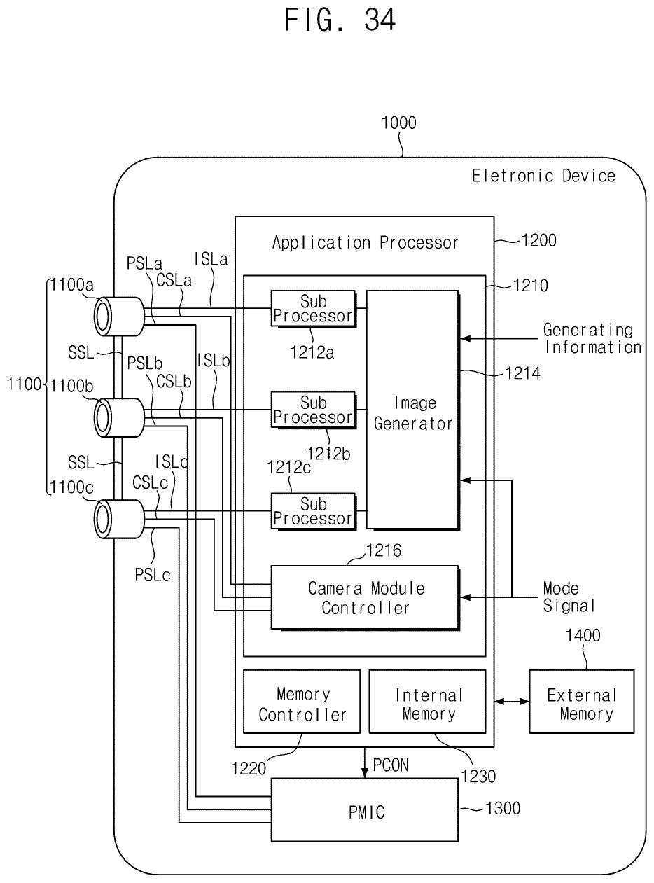

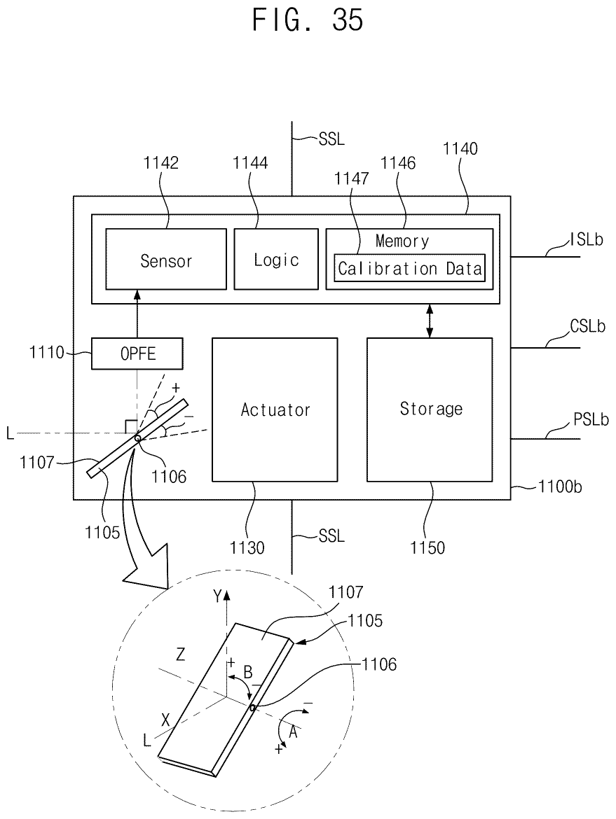

FIG. 34 is a block diagram illustrating an electronic device according to example embodiments, and FIG. 35 is a block diagram illustrating a camera module included in the electronic device of FIG. 34.

Referring to FIG. 34, an electronic device 1000 may include a camera module group 1100, and application processor 1200, a power management integrated circuit (PMIC) 1300 and/or an external memory 1400.

The camera module group 1100 may include a plurality of camera modules 1100a, 1100b, and 1100c. FIG. 34 illustrates the three camera modules 1100a, 1100b, and 1100c as an example, but the example embodiments are not limited to a particular number of camera modules. According to some example embodiments, the camera module group 1100 may include two camera modules, and/or four or more camera modules.

Hereinafter, an example configuration of the camera module 1100b is described with reference to FIG. 35. According to some example embodiments, the same descriptions may be applied to the other camera modules 1100a and 1100c.

Referring to FIG. 35, the camera module 1100b may include a prism 1105, an optical path folding element (OPFE) 1110, an actuator 1130, an image sensing device 1140 and a storage device 1150.

The prism 1105 may include a reflection surface 1107 to change a path of a light L incident on the prism 1105.

In some example embodiments, the prism 1105 may be configured to change the path of the light L incident in a first direction X to the path in a second direction Y perpendicular to the first direction X. In addition, the prism 1105 may rotate the reflection surface 1107 around a center axis 1106 and/or rotate the center axis 1106 in the B direction to align the path of the reflected light along the second direction Y. In addition, the OPFE 1110 may move in a third direction perpendicular to the first direction X and the second direction Y.

In some example embodiments, a rotation angle of the prism 1105 may be smaller than 15 degrees in the positive (+) A direction and greater than 15 degrees in the negative (−) A direction, but example embodiments are not limited thereto.

In some example embodiments, the prism 1105 may rotate within 20 degrees in the positive B direction and the negative B direction.

In some example embodiments, the prism 1105 may move the reflection surface 1107 in the third direction Z that is in parallel with the center axis 1106.

The OPFE 1110 may include optical lenses that are divided into m groups where m is a positive integer. The m lens group may move in the second direction Y to change an optical zoom ratio of the camera module 1100b. For example, the optical zoom ratio may be changed in a range of 3K, 5K, and so on by moving the m lens group, when K is a basic optical zoom ratio of the camera module 1100b.

The actuator 1130 may be configured to move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144, and/or a memory 1146. The image sensor 1142 may be configured to capture and/or sense an image using the light provided through the optical lens. The control logic 1144 may control overall operations of the camera module 1100b. For example, the control logic 1144 may provide control signals through control signal line CSLb to control the operation of the camera module 1100b. The image sensor 1142 may include, for example, an image sensor (e.g., the image sensor 600) and/or a pixel (e.g., the pixel PX) according to at least one of the above described embodiments.

The memory 1146 may store information such as calibration data 1147 for the operation of the camera module 1100b. For example, the calibration data 1147 may include information for generation of image data based on the provided light, such as information on the above-described rotation angle, a focal length, information on an optical axis, and so on. When the camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed using the image sensor 1142. The storage device 1150 may be disposed outside of the image sensing device 1140, and the storage device 1150 may be stacked with a sensor chip comprising the image sensing device 1140. The storage device 1150 may be implemented with an electrically erasable programmable read-only memory (EEPROM), but example embodiments are not limited thereto.

Referring to FIGS. 34 and 35, each of the camera modules 1100a, 1100b, and 1100c may include the actuator 1130. In some example embodiments, the camera modules 1100a, 1100b, and 1100c may include the same or different calibration data 1147 depending on the operations of the actuators 1130.

In some example embodiments, one camera module 1100b may have a folded lens structure included the above-described prism 1105 and the OPFE 1110, and the other camera modules 1100a and 1100b may have a vertical structure without the prism 1105 and the OPFE 1110.

In some example embodiments, one camera module 1100c may be a depth camera configured to measure distance information of an object using an infrared light. In some example embodiments, the application processor 1200 may merge the distance information provided from the depth camera 1100c and image data provided from the other camera modules 1100a and 1100b to generate a three-dimensional depth image.

In some example embodiments, at least two camera modules among the camera modules 1100a, 1100b, and 1100c may have different field of views, for example, through different optical lenses.

In some example embodiments, each of the camera modules 1100a, 1100b, and 1100c may be separated physically from each other. In other words, the camera modules 1100a, 1100b, and 1100c may each include a dedicated image sensor 1142.

The application processor 1200 may include an image processing device 1210, a memory controller 1220 and an internal memory 1230. The application processor 1200 may be separated from the camera modules 1100a, 1100b, and 1100c. For example, the application processor 1200 may be implemented as one chip and the camera modules 1100a, 1100b, and 1100c may implemented as another chip or other chips.

The image processing device 1210 may include a plurality of sub-processors 1212a, 1212b, and 1212c, an image generator 1214 and a camera module controller 1216.

The image data generated by the camera modules 1100a, 1100b, and 1100c may be provided to the sub-processors 1212a, 1212b, and 1212c through distinct image signal lines ISLa, ISLb, and ISLc, respectively. For example, the transfer of the image data may be performed using a camera serial interface (CSI) based on the mobile industry processor interface (MIPI), but example embodiments are not limited thereto.

In some example embodiments, one sub-processor may be assigned commonly to two or more camera modules. In some example embodiments, a multiplexer may be used to transfer the image data selectively from one of the camera modules to the shared sub-processor.

The image data from the sub-processors 1212a, 1212b, and 1212c may be provided to the image generator 1214. The image generator 1214 may generate an output image using the image data from the sub-processors 1212a, 1212b, and 1212c according to image generating information or a mode signal. For example, the image generator 1213 may merge at least a portion of the image data from the camera modules 1100a, 1100b, and 1100c having the different fields of view to generate the output image according to the image generating information or the mode signal. In addition, the image generator 1214 may select, as the output image, one of the image data from the camera modules 1100a, 1100b, and 1100c according to the image generating information or the mode signal.

In some example embodiments, the image generating information may include a zoom factor or a zoom signal. In some example embodiments, the mode signal may be a signal based on a selection of a user.

When the image generating information is the zoom factor and the camera modules 1100a, 1100b, and 1100c have the different field of views, the image generator 1214 may perform different operation depending on the zoom signal. For example, when the zoom signal is a first signal, the image generator 1214 may merge the image data from the different camera modules to generate the output image. When the zoom signal is a second signal different from the first signal, the image generator 1214 may select, as the output image, one of image data from the camera modules 1100a, 1100b, and 1100c.

In some example embodiments, the image generator 1214 may receive the image data of different exposure times from the camera modules 1100a, 1100b, and 1100c. In some example embodiments, the image generator 1214 may perform high dynamic range (HDR) processing with respect to the image data from the camera modules 1100a, 1100b, and 1100c to generate the output image having the increased dynamic range.

The camera module controller 1216 may provide control signals to the camera modules 1100a, 1100b, and 1100c. The control signals generated by the camera module controller 1216 may be provided to the camera modules 1100a, 1100b, and 1100c through the distinct control signal lines CSLa, CSLb, and CSLc, respectively.

In some example embodiments, one of the camera modules 1100a, 1100b, and 1100c may be designated as a master camera according to the image generating information of the mode signal, and the other camera modules may be designated as slave cameras.

The camera module acting as the master camera may be changed according to the zoom factor or an operation mode signal. For example, when the camera module 1100a has the wider field of view than the camera module 1100b and the zoom factor indicates a lower zoom magnification, the camera module 1100b may be designated as the master camera. In contrast, when the zoom factor indicates a higher zoom magnification, the camera module 1100a may be designated as the master camera.

In some example embodiments, the control signals provided from the camera module controller 1216 may include a synch enable signal. For example, when the camera module 1100b is the master camera and the camera modules 1100a and 1100c are the slave cameras, the camera module controller 1216 may provide the synch enable signal to the camera module 1100b. The camera module 1100b may generate a synch signal based on the provided synch enable signal and provide the synch signal to the camera modules 1100a and 1100c through a synch signal line SSL. As such, the camera modules 1100a, 1100b and 1100c may transfer the synchronized image data to the application processor 1200 based on the synch signal.

In some example embodiments, the control signals provided from the camera module controller 1216 may include information on the operation mode. The camera modules 1100a, 1100b, and 1100c may operate in a first operation mode or a second operation mode based on the information from the camera module controller 1216.

In the first operation mode, the camera modules 1100a, 1100b, and 1100c may generate image signals with a first speed (e.g., a first frame rate) and encode the image signals with a second speed higher than the first speed (e.g., a second frame rate higher than the first frame rate) to transfer the encoded image signals to the application processor 1200. The second speed may be lower than thirty times the first speed. The application processor 1200 may store the encoded image signals in the internal memory 1230 or the external memory 1400. The application processor 1200 may read out and decode the encoded image signals to provide display data to a display device. For example, the sub-processors 1212a, 1212b, and 1212c may perform the decoding operation and the image generator 1214 may process the decoded image signals.

In the second operation mode, the camera modules 1100a, 1100b, and 1100c may generate image signals with a third speed lower than the first speed (e.g., the third frame rate lower than the first frame rate) to transfer the generated image signals to the application processor 1200. In other words, the image signals that are not encoded may be provided to the application processor 1200. The application processor 1200 may process the received image signals or store the receive image signals in the internal memory 1230 or the external memory 1400.

The PMIC 1300 may be configured to provide a power supply voltage to the camera modules 1100a, 1100b, and 1100c, respectively. For example, the PMIC 1300 may provide, under control of the application processor 1200, a first power to the camera module 1100a through a power line PSLa, a second power to the camera module 1100b through a power line PSLb, and a third power to the camera module 1100c through a power line PSLc.

The PMIC 1300 may generate the power respectively corresponding to the camera modules 1100a, 1100b, and 1100c and control power levels, in response to a power control signal PCON from the application processor 1200. The power control signal PCON may include information on the power depending on the operation modes of the camera modules 1100a, 1100b, and 1100c. For example, the operation modes may include a low power mode in which the camera modules 1100a, 1100b, and 1100c operate in low powers. The power levels of the camera modules 1100a, 1100b, and 1100c may be the same as or different from each other. In addition, the power levels may be changed dynamically or adaptively.

As described above, the pixel and the image sensor according to example embodiments may efficiently improve the electrical characteristics of the pixel and the image sensor by adding only the bridge region of the simple structure to provide the overflow path.

The example embodiments may be applied to any electronic devices and systems including an image sensor. For example, the example embodiments may be applied to systems such as a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, an augmented reality (AR) device, a vehicle navigation device, a video phone, a monitoring system, an auto focusing system, a tracking system, a motion detection system, etc.

The foregoing is illustrative of example embodiments and is not to be construed as limiting thereof. Although a few example embodiments have been described, those skilled in the art will readily appreciate that many modifications are possible in the example embodiments without materially departing from the example embodiments.

What is claimed is:

1. A pixel of an image sensor, comprising:
a first photoelectric conversion region and a second photoelectric conversion region in a lower portion of a semiconductor substrate, the first photoelectric conversion region and the second photoelectric conversion region spaced apart from each other in a first horizontal direction;
a first floating diffusion region and a second floating diffusion region in an upper portion of the semiconductor substrate;
a first transfer gate and a second transfer gate above the semiconductor substrate;
a first pixel transistor on a side of the first transfer gate in a second horizontal direction perpendicular to the first horizontal direction, the first pixel transistor including a first source-drain region in the upper portion of the semiconductor substrate, a second source-drain region in the upper portion of the semiconductor substrate, and a first pixel gate above the semiconductor substrate and between the first source-drain region and the second source-drain region, and the second source-drain region configured to receive a pixel power voltage; and
a bridge region below the second source-drain region, the bridge region configured to form an overflow barrier potential such that redundant photo-charges from the first photoelectric conversion region and the second photoelectric conversion region are discharged to the second source-drain region.

2. The pixel of claim 1, wherein
the second source-drain region is doped with a first concentration of N-type impurities,
the bridge region is doped with a second concentration of N-type impurity, and
the second concentration is less than the first concentration.

3. The pixel of claim 1, wherein the second source-drain region extends in a vertical direction to a depth deeper than the first source-drain region, and at least a portion corresponding to the extended depth of the second source-drain region corresponds to the bridge region.

4. The pixel of claim 1, wherein the bridge region is in contact with the second source-drain region and is spaced apart from the first photoelectric conversion region in a vertical direction.

5. The pixel of claim 1, further comprising:
an inter-pixel trench structure surrounding the pixel and configured to isolate the pixel from neighboring pixels,
wherein the second source-drain region is more adjacent to the inter-pixel trench structure than to the first source-drain region.

6. The pixel of claim 1, further comprising:
an intra-pixel trench structure extending in the second horizontal direction to bisect the pixel and configured to isolate the first photoelectric conversion region and the second photoelectric conversion region,
wherein the intra-pixel trench structure includes a first portion and a second portion spaced apart from each other in the second horizontal direction.

7. The pixel of claim 1, wherein the overflow barrier potential is lower than a transfer barrier potential between the first photoelectric conversion region and the first floating diffusion region in a state that a turn-off voltage is applied to the first transfer gate.

8. The pixel of claim 1, wherein the overflow barrier potential is higher than an intra-barrier potential between the first photoelectric conversion region and the second photoelectric conversion region.

9. The pixel of claim 1, wherein the first pixel transistor corresponds to a reset transistor configured to apply the pixel power voltage to the first floating diffusion region and the second floating diffusion region.

10. The pixel of claim 1, wherein
the first pixel transistor corresponds to a source follower transistor, and
the first pixel gate is connected to the first floating diffusion region and the second floating diffusion region.

11. The pixel of claim 1, wherein a first length of the first photoelectric conversion region in the second horizontal direction is greater than a second length of the first photoelectric conversion region in the first horizontal direction and a first length of the second photoelectric conversion region in the second horizontal direction is greater than a second length of the second photoelectric conversion region in the first horizontal direction.

12. The pixel of claim 1, further comprising:
a common microlens overlapped in a vertical direction with both the first photoelectric conversion region and the second photoelectric conversion region, the common microlens configured to focus incident light towards the first photoelectric conversion region and the second photoelectric conversion region.

13. The pixel of claim 1, further comprising:
a second pixel transistor on a side of the second transfer gate in the second horizontal direction, the second pixel transistor including a third source-drain region in the upper portion of the semiconductor substrate, a fourth source-drain region in the upper portion of the semiconductor substrate, and a second pixel gate above the semiconductor substrate and between the third source-drain region and the fourth source-drain region.

14. The pixel of claim 13, wherein the second pixel transistor corresponds to a dummy transistor configured to receive a ground voltage at the second pixel gate.

15. An image sensor comprising:
a pixel array including a plurality of pixels configured to perform a sensing operation by collecting photo-charges generated by incident light;
a row driver configured to drive the pixel array in units of rows; and
a controller configured to control the pixel array and the row driver,
wherein a pixel of the plurality of pixels comprises
a first photoelectric conversion region and a second photoelectric conversion region in a lower portion of a semiconductor substrate, the first photoelectric conversion region and the second photoelectric conversion region spaced apart from each other in a first horizontal direction,
a first floating diffusion region and a second floating diffusion region in an upper portion of the semiconductor substrate,
a first transfer gate and a second transfer gate above the semiconductor substrate,
a first pixel transistor on a side of the first transfer gate in a second horizontal direction perpendicular to the first horizontal direction, the first pixel transistor including a first source-drain region in the upper portion of the semiconductor substrate, a second source-drain region in the upper portion of the semiconductor substrate, and a first pixel gate above the semiconductor substrate and between the first source-drain region and the second source-drain region, and the second source-drain region is configured to receive a pixel power voltage, and
a bridge region below the second source-drain region, the bridge region configured to form an overflow barrier potential such that redundant photo-charges from the first photoelectric conversion region and the second photoelectric conversion region are discharged to the second source-drain region.

16. The image sensor of claim 15, wherein the plurality of pixels are grouped into a plurality of pixel groups repeatedly arranged in the first horizontal direction and in the second horizontal direction,
wherein pixels included in a pixel group of the plurality of pixel groups share a readout circuit including a source follower transistor, a select transistor, and a reset transistor, and
wherein pixel transistors included in the pixel group correspond to the source follower transistor, the select transistor, and the reset transistor.

17. The image sensor of claim 16, wherein the pixel group includes at least two pixels, the at least two pixels including two pixels adjacent to each other in the first horizontal direction or the second horizontal direction.

18. The image sensor of claim 16, wherein the pixel group includes at least four pixels, the at least four pixels including four pixels in a matrix form of two rows and two columns such that the four pixels are adjacent to each other in the first horizontal direction and the second horizontal direction.

19. A pixel of an image sensor, comprising:
a first photoelectric conversion region in a lower portion of a semiconductor substrate;
a first floating diffusion region in an upper portion of the semiconductor substrate;
a first transfer gate above the semiconductor substrate;
a second photoelectric conversion region in the lower portion of the semiconductor substrate, the second photoelectric conversion region spaced apart from the first photoelectric conversion region in a first horizontal direction;
a second floating diffusion region in the upper portion of the semiconductor substrate, the second floating diffusion region spaced apart from the first floating diffusion region in the first horizontal direction:
a second transfer gate above the semiconductor substrate, the second transfer gate spaced apart from the first transfer gate in the first horizontal direction;
a first source-drain region and a second source-drain region in the upper portion of the semiconductor substrate, the second source-drain region configured to receive a pixel power voltage;
a first pixel gate above the semiconductor substrate and between the first source-drain region and the second source-drain region;
a third source-drain region and a fourth source-drain region in the upper portion of the semiconductor substrate, the fourth source-drain region configured to receive the pixel power voltage;
a second pixel gate above the semiconductor substrate and between the third source-drain region and the fourth source-drain region; and
at least one bridge region below at least one of the second source-drain region or the fourth source-drain region, the at least one bridge region configured to form an overflow barrier potential such that redundant photo-charges from the first photoelectric conversion region and the second photoelectric conversion region are discharged to the at least one of the second source-drain region or the fourth source-drain region.

20. The pixel of claim 19, wherein
the overflow barrier potential is lower than a transfer barrier potential between the first photoelectric conversion region and the first floating diffusion region in a state that a turn-off voltage is applied to the first transfer gate, and
the overflow barrier potential is higher than an intra-barrier potential between the first photoelectric conversion region and the second photoelectric conversion region.
